(19) United States
(12) Patent Application Publication
(10) Pub. No.: US 2025/0386694 A1
(43) Pub. Date: Dec. 18, 2025

(54) DISPLAY DEVICE AND ELECTRONIC DEVICE INCLUDING THEREOF

(71) Applicant: SAMSUNG DISPLAY CO., LTD., YONGIN-SI (KR)

(72) Inventors: Jun Hyun PARK, Yongin-si (KR); Sun Kwun SON, Yongin-si (KR); Cheol Gon LEE, Yongin-si (KR)

(21) Appl. No.: 19/217,603

(22) Filed: May 23, 2025

(30) Foreign Application Priority Data
Jun. 17, 2024 (KR) 10-2024-0078089
Jan. 21, 2025 (KR) 10-2025-0009062

(51) Int. Cl. H10K 59/131; H10H 29/34; H10H 29/39; H10H 29/49; H10K 59/121

(52) U.S. Cl. CPC H10K 59/131; H10H 29/34; H10H 29/39; H10H 29/49; H10K 59/121

(57) ABSTRACT

A display device includes a first pixel including a first sub-pixel, a second sub-pixel, and a third sub-pixel, wherein the first pixel is disposed in a first row, and a second pixel including a fourth sub-pixel, a fifth sub-pixel, and a sixth sub-pixel, the second pixel is disposed in the first row, the first sub-pixel and the fourth sub-pixel are adjacent to each other, emit light of a first color, and share a first data line, the second sub-pixel and the fifth sub-pixel are adjacent to each other, emit light of a second color, and share a second data line, and the sixth sub-pixel and the third sub-pixel are adjacent to each other, emit light of a third color, and share a third data line.

### CROSS-REFERENCE TO RELATED APPLICATION

This U.S. non-provisional patent application claims priority under 35 U.S.C. § 119 to Korean Patent Application Nos. 10-2024-0078089, filed on Jun. 17, 2024, and 10-2025-0009062, filed on Jan. 21, 2025, in the Korean Intellectual Property Office, the entire disclosures of which are incorporated by reference in their entireties.

### BACKGROUND

### 1. Technical Field

Embodiments of the present disclosure relate to a display device and an electronic device including the same. More specifically, embodiments of the present disclosure relate to a display device including a sub-pixels from different pixels sharing a data line.

### 2. Description of Related Art

As information technology advances, display devices, which serve as the interface between a user and information, are becoming increasingly significant. Accordingly, the demand for the use of display devices such as liquid crystal display devices and organic light-emitting display devices is increasing.

The display device may include a pixel circuit layer including circuits of sub-pixels and a light-emitting element layer including anode electrodes of the sub-pixels. To ensure proper functionality, the sub-pixels needs to be arranged in a way so that the wirings connecting the circuits of sub-pixels and the anode electrodes of the sub-pixels are not twisted.

### SUMMARY

A display device according to embodiments of the present disclosure includes a first pixel including a first sub-pixel, a second sub-pixel, and a third sub-pixel, wherein the first pixel is disposed in a first row; and a second pixel including a fourth sub-pixel, a fifth sub-pixel, and a sixth sub-pixel, wherein the second pixel is disposed in the first row, wherein the first sub-pixel and the fourth sub-pixel are adjacent to each other, emit light of a first color, and share a first data line, wherein the second sub-pixel and the fifth sub-pixel are adjacent to each other, emit light of a second color, and share a second data line, and wherein the third sub-pixel and the sixth sub-pixel are adjacent to each other, emit light of a third color, and share a third data line, and wherein the fifth sub-pixel is disposed adjacent to the sixth sub-pixel.

In some embodiments, the first sub-pixel and the fourth sub-pixel may emit a red color light, the second sub-pixel and the fifth sub-pixel may emit a blue color light, the third sub-pixel and the sixth sub-pixel may emit a green color light, and the sub-pixels emitting the red color light, the sub-pixels emitting the blue color light, and the sub-pixels emitting the green color light may be disposed sequentially in a first direction perpendicular to the first data line.

In some embodiments an arrangement order between the first sub-pixel and the fourth sub-pixel is same as an arrangement order between the second sub-pixel and the fifth sub-pixel.

In some embodiments the arrangement order between the first sub-pixel and the fourth sub-pixel be different from an arrangement order between the third sub-pixel and the sixth sub-pixel.

In some embodiments the first sub-pixel, the fourth sub-pixel, the second sub-pixel, the fifth sub-pixel, the sixth sub-pixel, and the third sub-pixel may be sequentially disposed.

In some embodiments, the display device may further include: a third pixel including a seventh sub-pixel, an eighth sub-pixel, and a ninth sub-pixel, wherein the third pixel is disposed in a second row below the first row; and a fourth pixel including a tenth sub-pixel, an eleventh sub-pixel, and a twelfth sub-pixel, wherein the fourth pixel is disposed in the second row, and wherein the seventh sub-pixel and the tenth sub-pixel are adjacent to each other, emit light of the first color and share the first data line, wherein the eighth sub-pixel and the eleventh sub-pixel are adjacent to each other, emit light of the second color and share the second data line, and wherein the ninth sub-pixel and the twelfth sub-pixel are adjacent to each other, emit light of the third color and share the third data line.

In some embodiments, the display device may further include a data driver applying a data signal to the first to third data lines, wherein the data driver may sequentially apply a data signal corresponding to the first sub-pixel, a data signal corresponding to the fourth sub-pixel, a data signal corresponding to the seventh sub-pixel, and a data signal corresponding to the tenth sub-pixel.

In embodiments, the first sub-pixel may be connected to a first odd-numbered gate line, the fourth sub-pixel may be connected to a first even-numbered gate line, the seventh sub-pixel may be connected to a second odd-numbered gate line, the tenth sub-pixel may be connected to a second even-numbered gate line, and a gate signal applied to the first odd-numbered gate line, the first even-numbered gate line, the second odd-numbered gate line, and the second even-numbered gate line may control timing at which the data signal is applied to the first sub-pixel, the fourth sub-pixel, the seventh sub-pixel, and the tenth sub-pixel, respectively.

In some embodiments, the display device may further include a data driver applying a data signal to the first data line, the second data line, and the third data line, wherein the data driver may sequentially apply a data signal corresponding to the first sub-pixel, a data signal corresponding to the fourth sub-pixel, a data signal corresponding to the tenth sub-pixel, and a data signal corresponding the seventh sub-pixel.

In embodiments, the first sub-pixel may be connected to a first odd-numbered gate line, the fourth sub-pixel may be connected to a first even-numbered gate line, the seventh sub-pixel may be connected to a second even-numbered gate line, the tenth sub-pixel may be connected to a second odd-numbered gate line, and a gate signal applied to the first odd-numbered gate line, the first even-numbered gate line, the second odd-numbered gate line, and the second even-numbered gate line may control timing at which the data signal is applied to the first sub-pixel, the fourth sub-pixel, the seventh sub-pixel, and the tenth sub-pixel, respectively.

In some embodiments, the display device may further include a pixel circuit layer including a first sub-pixel circuit of the first sub-pixel, a second sub-pixel circuit of the second sub-pixel, a third sub-pixel circuit of the third sub-pixel, a fourth sub-pixel circuit of the fourth sub-pixel, a fifth sub-pixel circuit of the fifth sub-pixel, and a sixth sub-pixel circuit of the sixth sub-pixel; and a light-emitting element layer including a first anode electrode of the first sub-pixel, a second anode electrode of the second sub-pixel, a third anode electrode of the third sub-pixel, a fourth anode electrode of the fourth sub-pixel, a fifth anode electrode of the fifth sub-pixel, and a sixth anode electrode of the sixth sub-pixel, wherein a wiring connected to the fourth sub-pixel circuit and the fourth anode electrode and a wiring connected to the fifth sub-pixel circuit and the fifth anode electrode may extend in a same direction.

In some embodiments, the first sub-pixel circuit, the fourth sub-pixel circuit, the second sub-pixel circuit, the fifth sub-pixel circuit, the sixth sub-pixel circuit, and the third sub-pixel circuit may sequentially be disposed in the first direction, and the first anode electrode, the sixth anode electrode, the second anode electrode, the fourth anode electrode, the third anode electrode, and the fifth anode electrode are may sequentially be disposed in the first direction.

In some embodiments, the wiring connected to the fourth sub-pixel circuit and the fourth anode electrode and the wiring connected to the fifth sub-pixel circuit and the fifth anode electrode may extend in the first direction.

In some embodiments, the sixth sub-pixel circuit, the third sub-pixel circuit, the first sub-pixel circuit, the fourth sub-pixel circuit, the second sub-pixel circuit, and the fifth sub-pixel circuit may sequentially be disposed in the first direction, and the first anode electrode, the third anode electrode, the second anode electrode, the fourth anode electrode, the sixth anode electrode, and the fifth anode electrode may sequentially be disposed in the first direction.

In embodiments, the wiring connected to the fourth sub-pixel circuit and the fourth anode electrode and the wiring connected to the fifth sub-pixel circuit and the fifth anode electrode may extend in a direction opposite to the first direction.

In embodiments, the first anode electrode may overlap the first sub-pixel circuit and the third sub-pixel circuit in a plan view, the second anode electrode may overlap the first sub-pixel circuit and the fourth sub-pixel circuit in a plan view, the third anode electrode may overlap the first sub-pixel circuit and the third sub-pixel circuit in a plan view, the fourth anode electrode may overlap the second sub-pixel circuit and the fifth sub-pixel circuit in a plan view, the fifth anode electrode may overlap the fifth sub-pixel circuit and the sixth sub-pixel circuit in a plan view, and the sixth anode electrode may overlap the second sub-pixel circuit and the fifth sub-pixel circuit in a plan view.

In embodiments, the pixel circuit layer further includes a seventh sub-pixel circuit of the seventh sub-pixel, an eighth sub-pixel circuit of the eighth sub-pixel, a ninth sub-pixel circuit of the ninth sub-pixel, a tenth sub-pixel circuit of the tenth sub-pixel, an eleventh sub-pixel circuit of the eleventh sub-pixel, and a twelfth sub-pixel circuit of the twelfth sub-pixel, and the light-emitting element layer further includes a seventh anode electrode of the seventh sub-pixel, an eighth anode electrode of the eighth sub-pixel, a ninth anode electrode of the ninth sub-pixel, a tenth anode electrode of the tenth sub-pixel, an eleventh anode electrode of the eleventh sub-pixel, and a twelfth anode electrode of the twelfth sub-pixel, wherein the seventh anode electrode may overlap the seventh sub-pixel circuit and the ninth sub-pixel circuit in a plan view, wherein the eighth anode electrode may overlap the seventh sub-pixel circuit and the tenth sub-pixel circuit in a plan view, wherein the ninth anode electrode may overlap the seventh sub-pixel circuit and the ninth sub-pixel circuit in a plan view, wherein the tenth anode electrode may overlap the eighth sub-pixel circuit and the eleventh sub-pixel circuit in a plan view, wherein the eleventh anode electrode may overlap the eleventh sub-pixel circuit and the twelfth sub-pixel circuit in a plan view, and the twelfth anode electrode may overlap the eighth sub-pixel circuit and the eleventh sub-pixel circuit in a plan view.

In embodiments, the first data line may overlap the second anode electrode and the eighth electrode in a plan view, the second data line may overlap the fourth anode electrode, the sixth anode electrode, the tenth anode electrode, and the twelfth anode electrode in a plan view, and the third data line may not overlap the anode electrodes.

In embodiments, the first anode electrode may overlap the first sub-pixel circuit and the fourth sub-pixel circuit in a plan view, the second anode electrode may overlap the fourth sub-pixel circuit and the second sub-pixel circuit in a plan view, the third anode electrode may overlap the first sub-pixel circuit and the fourth sub-pixel circuit in a plan view, the fourth anode electrode may overlap the fifth sub-pixel circuit and the sixth sub-pixel circuit in a plan view, the fifth anode electrode may overlap the sixth sub-pixel circuit in a plan view, and the sixth anode electrode may overlap the fifth sub-pixel circuit and the sixth sub-pixel circuit in a plan view.

In embodiments, the pixel circuit layer further includes a seventh sub-pixel circuit of the seventh sub-pixel, an eighth sub-pixel circuit of the eighth sub-pixel, a ninth sub-pixel circuit of the ninth sub-pixel, a tenth sub-pixel circuit of the tenth sub-pixel, an eleventh sub-pixel circuit of the eleventh sub-pixel, and a twelfth sub-pixel circuit of the twelfth sub-pixel, and the light-emitting element layer further includes a seventh anode electrode of the seventh sub-pixel, an eighth anode electrode of the eighth sub-pixel, a ninth anode electrode of the ninth sub-pixel, a tenth anode electrode of the tenth sub-pixel, an eleventh anode electrode of the eleventh sub-pixel, and a twelfth anode electrode of the twelfth sub-pixel, wherein the seventh anode electrode may overlap the seventh sub-pixel circuit and the tenth sub-pixel circuit in a plan view, wherein the eighth anode electrode may overlap the tenth sub-pixel circuit and the eighth sub-pixel circuit in a plan view, wherein the ninth anode electrode may overlap the seventh sub-pixel circuit and the tenth sub-pixel circuit in a plan view, wherein the tenth anode electrode overlaps the eleventh sub-pixel circuit and the twelfth sub-pixel circuit in a plan view, wherein the eleventh anode electrode may overlap the twelfth sub-pixel circuit in a plan view, and wherein the twelfth anode electrode may overlap the eleventh sub-pixel circuit and the twelfth sub-pixel circuit in a plan view.

In embodiments, the first data line may overlap the first anode electrode, the third anode electrode, the seventh anode electrode, and the ninth anode electrode in a plan view, the second data line may not overlap the anode electrodes in a plan view, and the third data line may overlap the fifth anode electrode and the eleventh anode electrode in a plan view.

An electronic device according to embodiments of the present disclosure includes a processor; and a display device displaying an image under controlling of the processor, wherein the display device includes: a first pixel including a first sub-pixel, a second sub-pixel, and a third sub-pixel; and a second pixel including a fourth sub-pixel, a fifth sub-pixel, and a sixth sub-pixel, wherein the second pixel is disposed in a same row as the first pixel, wherein the first sub-pixel and the fourth sub-pixel are adjacent to each other, emit a red light, and share a first data line, wherein the second sub-pixel and the fifth sub-pixel are adjacent to each other, emit a blue light, and share a second data line, and wherein the third sub-pixel and the sixth sub-pixel are adjacent to each other, emit a green light, and share a third data line.

### BRIEF DESCRIPTION OF THE DRAWINGS

FIG. 1 is a block diagram illustrating a display device according to an embodiment of the present disclosure.

FIG. 2 is an example of a block diagram illustrating one of sub-pixels in FIG. 1.

FIG. 3 is an example of a circuit diagram illustrating the sub-pixel in FIG. 2.

FIG. 4 is an example of a plan view illustrating a display panel of FIG. 1.

FIG. 5 is an example of an exploded perspective view of a part of the display panel of FIG. 4.

FIG. 6 is a block diagram illustrating sub-pixels sharing a data line according to an embodiment of the present disclosure.

FIG. 7 is a block diagram illustrating a pixel including the sub-pixels sharing the data line according to an embodiment of the present disclosure.

FIG. 8 is a block diagram illustrating a pixel including the sub-pixels sharing the data line according to an embodiment of the present disclosure.

FIG. 9 is a diagram illustrating a connection relationship between a pixel circuit layer and an anode electrode according to an embodiment of the present disclosure.

FIG. 10 is a diagram illustrating the connection relationship between the pixel circuit layer and the anode electrode according to an embodiment of the present disclosure.

FIG. 11 is a perspective view illustrating the connection relationship between the pixel circuit layer and the anode electrode according to an embodiment of the present disclosure.

FIG. 12 is a plan view illustrating the connection configuration between the pixel circuit layer and the anode electrode according to an embodiment of the present disclosure.

FIG. 13 is a plan view illustrating the connection configuration between the pixel circuit layer and the anode electrode according to an embodiment of the present disclosure.

FIG. 14 is a block diagram illustrating an electronic device according to embodiments of the present invention.

FIG. 15 is a diagram illustrating an example in which the electronic device is implemented as a smartphone.

### DETAILED DESCRIPTION

Hereinafter, preferred embodiments of the present invention are described in detail with reference to the accompanying drawings. It should be noted that in the following description, the parts necessary to understand the operation according to the present invention are described, and the description of other parts may be omitted so as not to obscure the gist of the present invention. Furthermore, the present invention is not limited to the embodiments described herein, and may be embodied in other forms. However, the embodiments described herein are provided to explain the technical idea of the present invention in detail to a person having ordinary skill in the art to which the present invention pertains so that the technical idea can be easily implemented.

Throughout the specification, when a part is “connected” to another part, this includes not only “directly connected” but also “indirectly connected” with another element interposed therebetween. For example, a first layer connected to a second layer may represent the first layer directly connected to the second layer or the first layer is connected to the second layer having an intermediate layer disposed therebetween. The terminology used herein is for the purpose of describing particular embodiments and is not intended to limit the invention.

Throughout the specification, when a part “comprises” a certain component, other components may be further included instead of excluding other components unless otherwise specified. “At least one of X, Y, and Z” and “at least one selected from the group consisting of X, Y and Z” may be interpreted as one X, one Y, one Z, or any combination of two or more of X, Y or Z (e.g., XYZ, XYY, YZ, ZZ). As used herein, “and/or” includes any combination of one or more of those elements.

As used herein, although terms such as first, second, etc. may be used to describe various components, these components are not limited to these terms. These terms are used to distinguish one component from another. Thus, a first component may refer to a second component without departing from what is disclosed herein.

Spatially relative terms such as “below”, “above”, and the like may be used for purposes of explanation, thereby describing the relationship of one element or feature to another element(s) or feature(s), as illustrated in the figures. Spatially relative terms are intended to include different directions in use, operation, and/or manufacture in addition to the directions depicted in the figures. For example, if the device shown in the figure is inverted, the elements depicted as being “below” other elements or features are positioned in the direction “above” the other elements or features. Thus, in one embodiment, the term “below” may include both directions. Furthermore, the device may be directed in another direction (e.g., rotated 90 degrees or in another direction), and thus the spatially relative terms used herein are interpreted accordingly.

Various embodiments are described with reference to the figures schematizing ideal embodiments. It will thus be envisaged that the shapes may vary, for example, based on tolerances and/or manufacturing techniques. Accordingly, the embodiments disclosed herein are not to be construed as limited to the particular shapes shown, but are to be construed as including, for example, changes in shapes that occur as a result of fabrication. As such, the shapes shown in the figures may not show actual shapes of regions of the apparatus, and the present embodiments are not limited thereto.

Embodiments of the present disclosure provide a display device that includes a pixel arrangement and wiring configuration optimized to minimize parasitic capacitance, improve voltage stability, and enhance power efficiency. In some embodiments, the display device includes a first sub-pixel circuit and a second sub-pixel circuit disposed adjacent to a data line, wherein the first sub-pixel circuit and the second sub-pixel circuit share the same data line to reduce the frequency of charging and lower the power consumption. The display device also includes a first anode electrode and a second anode electrode electrically connected to the corresponding sub-pixel circuits, wherein the wiring between the sub-pixel circuits and the anode electrodes extends in a uniform direction to prevent signal interference and reduce unwanted parasitic capacitance. In some cases, the arrangement of the gate lines follows an alternating pattern to prevent wiring twists and ensure consistent luminance across the display panel.

As used herein, a first sub-pixel, a second sub-pixel, and a third sub-pixel may be referred to as the first sub-pixel R11, second sub-pixel B11, and third sub-pixel G11, respectively, of the first pixel PXL1. The fourth sub-pixel, a fifth sub-pixel, and a sixth sub-pixel may be referred to as the first sub-pixel R12, second sub-pixel B12, and third sub-pixel G12, respectively, of the second pixel PXL2. The seventh sub-pixel, an eighth sub-pixel, and a ninth sub-pixel may be referred to as the first sub-pixel R21, second sub-pixel B21, and third sub-pixel G21, respectively, of the third pixel PXL3. The tenth sub-pixel, an eleventh sub-pixel, and a twelfth sub-pixel may be referred to as the first sub-pixel R22, second sub-pixel B22, and third sub-pixel G22, respectively, of the fourth pixel PXL4.

A first sub-pixel circuit of the first sub-pixel, a second sub-pixel circuit of the second sub-pixel, a third sub-pixel circuit of the third sub-pixel, a fourth sub-pixel circuit of the fourth sub-pixel, a fifth sub-pixel circuit of the fifth sub-pixel, and a sixth sub-pixel circuit of the sixth sub-pixel may be referred to as the first sub-pixel circuit R1, second sub-pixel circuit B1, third sub-pixel circuit G1, first sub-pixel circuit R2, second sub-pixel circuit B2, and third sub-pixel circuit G2, respectively.

A first anode electrode of the first sub-pixel, a second anode electrode of the second sub-pixel, a third anode electrode of the third sub-pixel, a fourth anode electrode of the fourth sub-pixel, a fifth anode electrode of the fifth sub-pixel, and a sixth anode electrode of the sixth sub-pixel may be referred to as the first anode electrode RA1, second anode electrode BA1, third anode electrode GA1, first anode electrode RA2, second anode electrode BA2, and third anode electrode GA2, respectively.

A seventh sub-pixel circuit of the seventh sub-pixel, an eighth sub-pixel circuit of the eighth sub-pixel, a ninth sub-pixel circuit of the ninth sub-pixel, a tenth sub-pixel circuit of the tenth sub-pixel, an eleventh sub-pixel circuit of the eleventh sub-pixel, and a twelfth sub-pixel circuit of the twelfth sub-pixel may be referred to as first sub-pixel circuit R3, second sub-pixel circuit B3, third sub-pixel circuit G3, first sub-pixel circuit R4, second sub-pixel circuit B4, and third sub-pixel circuit G4, respectively.

A seventh anode electrode of the seventh sub-pixel, an eighth anode electrode of the eighth sub-pixel, a ninth anode electrode of the ninth sub-pixel, a tenth anode electrode of the tenth sub-pixel, an eleventh anode electrode of the eleventh sub-pixel, and a twelfth anode electrode of the twelfth sub-pixel may be referred to as first anode electrode RA3, second anode electrode BA3, third anode electrode GA3, first anode electrode RA4, second anode electrode BA4, and third anode electrode GA4, respectively.

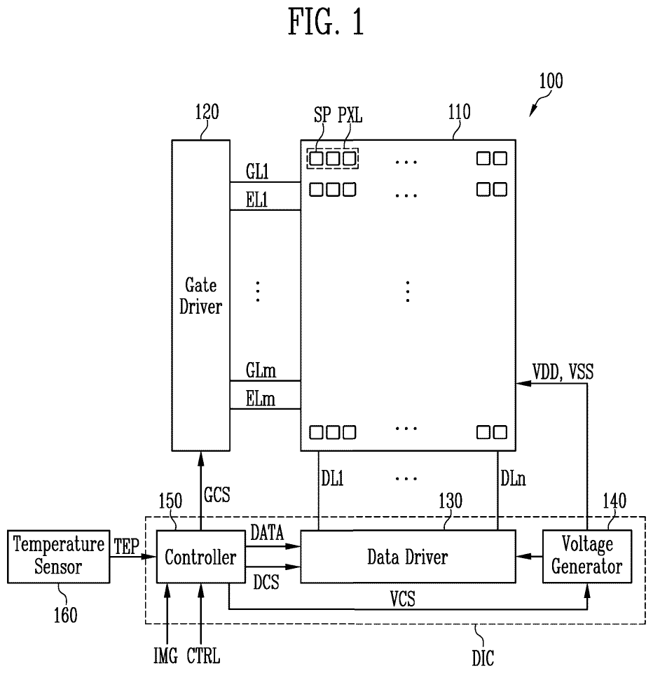

FIG. 1 is a block diagram illustrating a display device 100 according to an embodiment of the present disclosure. Referring to FIG. 1, the display device 100 may include a display panel 110, a gate driver 120, a data driver 130, a voltage generator 140, and a controller 150.

The display panel 110 may include sub-pixels SP. The sub-pixels SP may be connected to the gate driver 120 through first to m-th gate lines GL1 to GLm. In some aspects, the sub-pixels SP may be connected to the first to m-th emitting control lines EL1 to Elm. The sub-pixels SP may be connected to the data driver 130 through first to n-th data lines DL1 to DLn.

Each of the sub-pixels SP may include at least one light-emitting element configured to generate light. Accordingly, each of the sub-pixels SP may generate light of a color, such as red, green, blue, cyan, magenta, yellow, or the like. Two or more sub-pixels of the sub-pixels SP may form one pixel PXL. For example, as shown in FIG. 1, three sub-pixels may form one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS generated from the controller 150. In some embodiments, the gate control signal GCS may include a start signal indicating the start of each frame, a horizontal synchronization signal to output gate signals in synchronization with the timing at which the data signals are applied, or the like.

In some embodiments, the sub-pixels SP may be further connected to first to m-th emitting control lines EL1 to ELm in the row direction parallel to the first to m-th gate lines GL1 to GLm. For example, the gate driver 120 may include a light-emitting control driver configured to control the first to m-th light-emitting control lines EL1 to Elm. In one aspect, the controller 150 may control the operation of the light-emitting control driver.

The gate driver 120 may be disposed on one side of the display panel 110. However, embodiments are not limited thereto. For example, the gate driver 120 may be divided into two or more drivers which are physically and/or logically divided, and the one of the drivers may be disposed on the one side of the display panel 110 and the other driver may be disposed on an opposite side of the display panel 110. As such, the gate driver 120 may be disposed around the display panel 110 in various forms according to some embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate or perform functions in response to the data control signal DCS. In some embodiments, the data control signal DCS may include a source start pulse, a source shift clock, a source output enable signal, or the like.

The data driver 130 may receive a power source (e.g., voltages) from the voltage generator 140 to apply data signals having grayscale voltages corresponding to the image data DATA to the first to n-th data lines DL1 to DLn. When a gate signal is applied to each of the first to m-th gate lines GL1 to GLm, the data signals corresponding to the image data DATA may be applied to the data lines DL1 to DLm. Accordingly, the sub-pixels SP may generate light corresponding to the data signals. Therefore, an image is displayed on the display panel 110.

In some embodiments, the gate driver 120 and the data driver 130 may include complementary metal-oxide semiconductor (CMOS) circuit elements. For example, CMOS circuit elements may include NMOS and PMOS transistors, which work together to form energy-efficient digital and analog circuits.

The voltage generator 140 may operate in response to a voltage control signal VCS generated from the controller 150. The voltage generator 140 may generate a plurality of voltages and provide the generated voltages to components of the display device 100. For example, the voltage generator 140 may generate the plurality of voltages by receiving an input voltage from a component or element that is not part of the display device 100, adjusting the received voltage, and regulating the adjusted voltage.

The voltage generator 140 may generate a first power supply voltage VDD and a second power supply voltage VSS, and the generated first and second power supply voltages VDD and VSS may be provided to the sub-pixels SP. The first power supply voltage VDD may have a relatively high voltage level, and the second power supply voltage VSS may have a lower voltage level than the first power supply voltage VDD. In some embodiments, the first power supply voltage VDD or the second power supply voltage VSS may be provided by an external device of the display device 100.

In some cases, the voltage generator 140 may generate various voltages. For example, the voltage generator 140 may generate an initialization voltage applied to the sub-pixels SP. For example, in a sensing operation for sensing electrical characteristics of transistors and/or light-emitting elements of the sub-pixels SP, a predetermined reference voltage may be applied to the first to n-th data lines DL1 to DLn, and the voltage generator 140 may generate the predetermined reference voltage.

The controller 150 may control various operations of the display device 100. The controller 150 may receive input image data IMG and a control signal CTRL for controlling the display thereof. The controller 150 may provide the gate control signal GCS, the data control signal DCS, and the voltage control signal VCS in response to the control signal CTRL. For example, the controller 150 may provide the gate control signal GCS to the gate driver 120. The controller 150 may provide the data control signal DCS to the data driver 130. The controller 150 may provide the voltage control signal VCS to the voltage generator 140.

The controller 150 may output the image data DATA by converting the input image data IMG to match the specification of the display device 100 or the display panel 110. In some embodiments, the controller 150 may output the image data DATA by aligning the input image data IMG to fit the sub-pixels SP in a unit of rows.

Two or more components of the data driver 130, the voltage generator 140, and the controller 150 may be mounted in one integrated circuit (IC). As illustrated in FIG. 1, the data driver 130, the voltage generator 140, and the controller 150 may be included in a driver integrated circuit DIC. For example, the data driver 130, the voltage generator 140, and the controller 150 may be functionally distinct components integrated in one driver integrated circuit DIC. In some embodiments, at least one of the data driver 130, the voltage generator 140, and the controller 150 may be provided as a component separate from a driver integrated circuit DIC.

The display device 100 may include at least one temperature sensor 160. The temperature sensor 160 may be configured to sense the temperature around thereof and generate temperature data TEP indicating the sensed temperature. In some embodiments, the temperature sensor 160 may be disposed adjacent to the display panel 110 and/or the driver integrated circuit DIC.

In an embodiment, the temperature sensor generates the temperature data TEP and provide the temperature data TEP to the controller 150. The controller 150 may control various operations of the display device 100 in response to the temperature data TEP. In some embodiments, the controller 150 may adjust a luminance of the image output from the display panel 110 in response to the temperature data TEP. For example, the controller 150 may adjust the data signals and the first and second power supply voltages VDD and VSS by controlling the components such as the data driver 130 and/or the voltage generator 140.

The display panel 110 may include the sub-pixels SP. The sub-pixels SP may be connected to the gate driver 120 through the first to m-th gate lines GL1 to GLm. The sub-pixels SP may be connected to the data driver 130 through the first to n-th data lines DL1 to DLn.

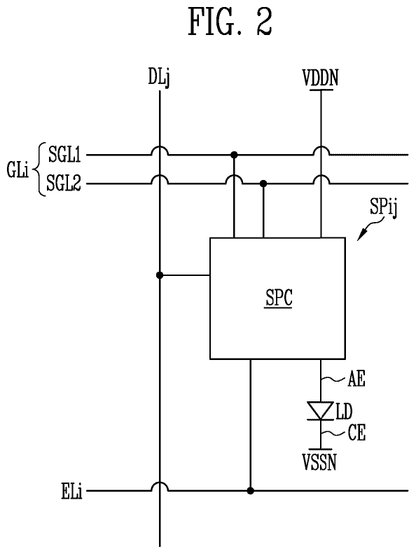

FIG. 2 is an example of a block diagram illustrating one of the sub-pixels SP in FIG. 1. Referring to FIG. 2, among the sub-pixels SP in FIG. 1, a sub-pixel SPij arranged in an i-th row (where i is an integer greater than or equal to 1 and less than or equal to m) and a j-th column (where j is an integer greater or equal to 1 and less than or equal than n) is illustrated as an example.

Referring to FIG. 2, the sub-pixel SPij may include a sub-pixel circuit SPC and a light-emitting element LD. The light-emitting element LD may be connected between a first power supply voltage node VDDN and a second power supply voltage node VSSN. The first power supply voltage node VDDN may transmit the first power supply voltage VDD of FIG. 1, and the second power supply voltage node VSSN may transmit the second power supply voltage VSS of FIG. 1.

An anode electrode AE of the light-emitting element LD may be connected to the first power supply voltage node VDDN through the sub-pixel circuit SPC, and a cathode electrode CE of the light-emitting element LD may be connected to the second power supply voltage node VSSN. For example, the anode electrode AE of the light-emitting element LD may be connected to the first power supply voltage node VDDN via one or more transistors included in the sub-pixel circuit SPC.

The sub-pixel circuit SPC may be connected to the i-th gate line GLi among the first to m-th gate lines GL1 to GLm of FIG. 1, the i-th light-emitting control line ELi among the first to n-th light-emitting control lines EL1 to ELm of FIG. 1, and the j-th data line DLj among the first to n-th data lines DL1 to DLn of FIG. 1. The sub-pixel circuit SPC may be configured to control the light-emitting element LD based on the signals received through the signal lines (e.g., the gate line GLi, the light-emitting control line ELi, and the data line DLi).

The sub-pixel circuit SPC may operate in response to a gate signal received through the i-th gate line GLi. The i-th gate line GLi may include one or more sub-gate lines. In some embodiments, as illustrated in FIG. 2, the i-th gate line GLi may include first sub-gate line SGL1 and second sub-gate line SGL2. The sub-pixel circuit SPC may operate in response to gate signals received through the first and second sub-gate lines SGL1 and SGL2. When the i-th gate line GLi includes two or more sub-gate lines, the sub-pixel circuit SPC may operate in response to gate signals received through the corresponding sub-gate lines.

The sub-pixel circuit SPC may operate in response to a light-emitting control signal received through the i-th light-emitting control line ELi. In some embodiments, the i-th light-emitting control line ELi may include one or more sub-light-emitting control lines. When the i-th light-emitting control line ELi includes two or more sub-light-emitting control lines, the sub-pixel circuit SPC may operate in response to light-emitting control signals received through the sub-light-emitting control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the light-emitting control signal received through the i-th light-emitting control line ELi, the sub-pixel circuit SPC may adjust the current flowing from the first power supply voltage node VDDN to the second power supply voltage node VSSN through the light-emitting element LD based on the stored voltage. Accordingly, the light-emitting element LD may generate light of a luminance corresponding to the data signal.

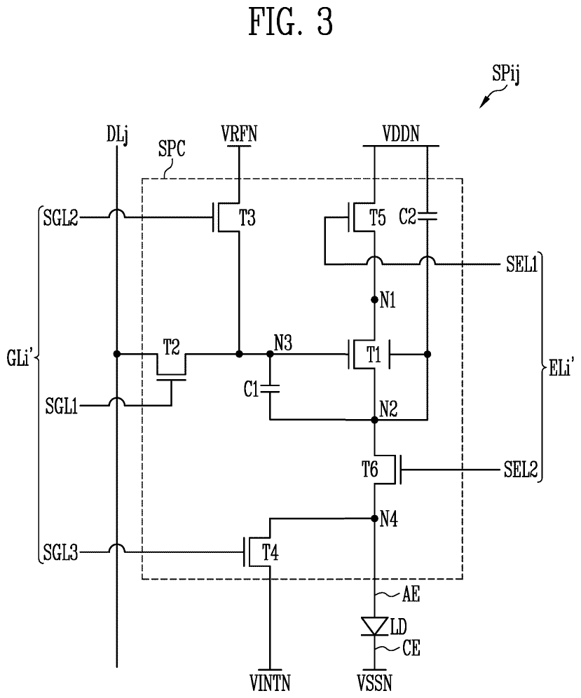

FIG. 3 is an example of a circuit diagram illustrating the sub-pixel SP in FIG. 2. Referring to FIG. 3, the sub-pixel SPij may include the sub-pixel circuit SPC and the light-emitting element LD. In one aspect, the sub-pixel circuit SPC may include a plurality of transistors including a first transistor T1, a second transistor T2, a third transistor T3, a fourth transistor T4, a fifth transistor T5, and a six transistor T6, and a plurality of capacitors including a first capacitor C1 and a second capacitor C2.

The sub-pixel circuit SPC may be connected to an i-th gate line GLi′, an i-th light-emitting control line ELi′, and the j-th data line DLj. Compared with the i-th gate line GLi in FIG. 2, the i-th gate line GLi′ may further include a third sub-gate line SGL3. Compared with the i-th light-emitting control line ELi in FIG. 2, the i-th emitting control line ELi′ may include a first sub-light-emitting control line SEL1 and a second sub-light-emitting control line SEL2.

The first transistor T1 may be connected between a first node N1 and a second node N2, which receive the first power supply voltage VDD through a first power supply voltage node VDDN. A gate electrode of the first transistor T1 may be connected to a third node N3 and the first transistor T1 may be turned on based on the voltage level of the third node N3. In one aspect, the second capacitor C2 may be disposed and connected between the first power supply voltage node VDDN and the second node N2. The first transistor T1 may be referred to as a driving transistor.

The second transistor T2 may be connected between the j-th data line DLj and the third node N3. A gate electrode of the second transistor T2 may be connected to the first sub-gate line SGL1, and the second transistor T2 may be turned on in response to a sub-gate signal of the first sub-gate line SGL1. When the second transistor T2 is turned on, a data voltage may be provided to the third node N3. The second transistor T2 may be referred to as a switching transistor.

The third transistor T3 may be connected between a reference voltage node VRFN and the third node N3. The reference voltage node VRFN may deliver a reference voltage. In some embodiments, the reference voltage may be provided by the voltage generator 140 in FIG. 1. The reference voltage may have a value between values of the first power supply voltage VDD and the second power supply voltage VSS.

A gate electrode of the third transistor T3 may be connected to the second sub-gate line SGL2 and the third transistor T3 may be turned on in response to a sub-gate signal of the second sub-gate line SGL2. When the third transistor T3 is turned on, the reference voltage may be provided to the third node N3.

The fourth transistor T4 may be connected between a fourth node N4 and an initialization voltage node VINTN. The initialization voltage node VINTN may deliver an initialization voltage. In some embodiments, the initialization voltage may be provided by the voltage generator 140 in FIG. 1. The initialization voltage may have a value between the values of the first power supply voltage VDD and the second power supply voltage VSS.

A gate electrode of the fourth transistor T4 may be connected to the third sub-gate line SGL3, and the fourth transistor T4 may be turned on in response to a sub-gate signal of the third sub-gate line SGL3.

The fifth transistor T5 may be connected between the first power supply voltage node VDDN and the first node N1. A gate electrode of the fifth transistor T5 may be connected to the first sub-light-emitting control line SEL1 and the fifth transistor T5 may be turned on in response to a first sub-light-emitting control signal of the first sub-light-emitting control line SEL1. The first node N1 may receive the first power supply voltage VDD through the fifth transistor T5.

The sixth transistor T6 may be connected between the second node N2 and the fourth node N4, which is connected to the anode electrode (AE) of the light-emitting element LD. A gate electrode of the sixth transistor T6 may be connected to the second sub-light-emitting control line SEL2 and the sixth transistor T6 may be turned on in response to a second sub-light-emitting control signal of the second sub-light-emitting control line SEL2.

The first capacitor C1 may be connected between the second node N2 and the third node N3. A voltage corresponding to the data signal may be stored in the first capacitor C1.

The second capacitor C2 may be connected between the first power supply voltage node VDDN and the second node N2. The second capacitor C2 may stabilize a voltage of the second node N2. In some cases, the second capacitor C2 maintains a stable voltage at node N2 by reducing fluctuations caused by transistor switching, ensuring consistent performance of the driving transistor T1.

As described above, the sub-pixel circuit SPC may include the first to sixth transistors T1 to T6, the first capacitor C1, and the second capacitor C2. However, embodiments are not limited thereto.

The sub-pixel circuit SPC may be implemented in various forms, including a plurality of transistors and one or more capacitors, or the like. For example, the sub-pixel circuit SPC may include two transistors and one capacitor. According to some embodiments of the sub-pixel circuit SPC, the number of the sub-gate lines included in the i-th gate line GLi′ and the number of the sub-light-emitting control lines included in the i-th light-emitting control line ELi′ may vary.

Each of the first to sixth transistors T1 to T6 may be a metal oxide silicon field effect transistor (MOSFET). A MOSFET is a semiconductor device used for switching and amplification in electronic circuits. In one aspect, the MOSFET includes three terminals (e.g., gate, drain, and source) where the gate voltage controls the flow of current between the drain and source. MOSFETs includes N-type (NMOS) and P-type (PMOS).

Each of the first to sixth transistors T1 to T6 may be an N-type transistor. For example, the turn-on level may be a high voltage level, and the turn-off level may be a low voltage level. When a signal applied to a gate electrode of the N-type transistor has a low voltage level, the N-type transistor may be turned off. For example, when a signal applied to the gate electrode of the N-type transistor has a high voltage level, the N-type transistor may be turned on.

However, the present disclosure is not limited thereto. For example, some of the first to sixth transistors T1 to T6 may be a as P-type transistors. For example, the turn-on level may be a low voltage level and the turn-off level may be a high voltage level. For example, when a signal applied to a gate electrode of the P-type transistor has a low voltage level, the P-type transistor may be turned on. For example, when a signal applied to the gate electrode of the P-type transistor has a high voltage level, the P-type transistor may be turned off.

Hereinafter, the phrase “a sub-gate signal is supplied” may be understood as the sub-gate signal being supplied at a logic level which turns on the transistor controlled thereby. In addition, the phrase “supply of the sub-gate signal is interrupted” may be understood as the sub-gate signal being supplied at the logic level which turns off the transistor controlled thereby.

In addition, the phrase “a light-emitting control signal is supplied” may be understood as the light-emitting control signal being supplied at a logic level which turns on the transistor controlled thereby. In addition, the phrase “supply of the light-emitting control signal is interrupted” may be understood as the light-emitting controlling signal being supplied at the logic level which turns off the transistor controlled thereby.

The light-emitting element LD may include the anode electrode AE, the cathode electrode CE, and a light-emitting layer. The light-emitting layer may be disposed between the anode electrode AE and the cathode electrode CE. After the data signal transmitted through the j-th data line DLj is reflected in the voltage of the third node N3, the fifth and sixth transistors T5 and T6 may be turned on when a first light-emitting control signal applied to the first sub-light-emitting control line SEL1 and a second light-emitting control signal applied to the second sub-light-emitting control line SEL2 are enabled to a high voltage level.

In addition, the first transistor T1 may be turned on based on the voltage of the third node N3 and a current may flow from the first power supply voltage node VDDN to the second power supply voltage node VSSN. The light-emitting element LD may emit light based on the amount of the current flowing therethrough.

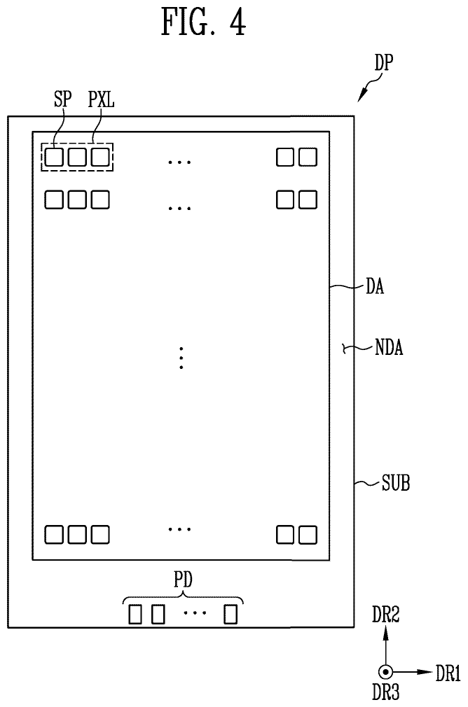

FIG. 4 is an example of a plan view illustrating the display panel 110 of FIG. 1 (e.g., display panel DP). Referring to FIG. 4, the display panel DP may include a display area DA and a non-display area NDA. The display panel DP may display an image through the display area DA. The non-display area NDA may surround the display area DA. The display panel DP may include a substrate SUB, the sub-pixels SP, and pads PD.

When the display panel DP is used as a display panel of a head-mounted display device (HMD) device, a virtual reality (VR) device, a mixed reality (MR) device, an augmented reality (AR) device, or the like, the display panel DP may be located close to the eyes of a user. As a result, the sub-pixels SP with a relatively high degree of integration may be required. In order to increase the degree of integration of the sub-pixels SP, the substrate SUB may be provided as a silicon substrate. The sub-pixels SP and/or the display panel DP may be formed on the substrate SUB including a silicon substrate. The display device 100 (refer to FIG. 1) including the display panel DP formed on the substrate SUB including a silicon substrate may be referred to as an OLED on Silicon (OLEDOS) display device.

The sub-pixels SP may be disposed in the display area DA on the substrate SUB. The sub-pixels SP may be arranged in a matrix form in a first direction DR1 and a second direction DR2 intersecting the first direction DR1. However, embodiments are not limited thereto. For example, the sub-pixels SP may be arranged in a zigzag form in the first direction DR1 and the second direction DR2. For example, the sub-pixels SP may be arranged in pentile form. The first direction DR1 may be a row direction and the second direction DR2 may be a column direction. Two or more sub-pixels of the plurality of sub-pixels SP may form one pixel PXL.

In the non-display area NDA on the substrate SUB, a component for controlling the sub-pixels SP may be disposed. For example, wirings connected to the sub-pixels SP such as the first to m-th gate lines GL1 to GLm and the first to n-th data lines DL1 to DLn of FIG. 1 may be disposed in the non-display area NDA.

At least one of the gate driver 120, the data driver 130, the voltage generator 140, the controller 150, and the temperature sensor 160 of FIG. 1 may be integrated in the non-display area NDA of the display panel DP. In some embodiments, the gate driver 120 of FIG. 1 may be mounted to the display panel DP and disposed in the non-display area NDA. In some embodiments, the gate driver 120 may be implemented as an integrated circuit separate from the display panel DP. In some embodiments, the temperature sensor 160 may be disposed in the non-display area NDA to sense the temperature of the display panel DP.

The pads PD may be disposed in the non-display area NDA on the substrate SUB. The pads PD may be electrically connected to the sub-pixels SP through the wirings. For example, the pads PD may be connected to the sub-pixels SP through the first to n-th data lines DL1 to DLn.

The pads PD may facilitate the interface between the display panel DP to other components of the display device 100 (refer to FIG. 1). In some embodiments, various voltages and signals for operating the components in the display panel DP may be provided from the driver integrated circuit DIC of FIG. 1 through the pads PD. For example, the first to n-th data lines DL1 to DLn may be connected to the driver integrated circuit DIC via the pads PD. For example, the first and second power supply voltages VDD and VSS may be received from the driver integrated circuit DIC via the pads PD. For example, when the gate driver 120 is mounted on the display panel DP, the gate control signal GCS may be transmitted from the driver integrated circuit DIC to the gate driver 120 through the pads PD.

In some embodiments, a circuit board may be electrically connected to the pads PD using a conductive adhesive such as an anisotropic conductive film. For example, the circuit board may be a flexible circuit board (FPCB) or a flexible film having a flexible material. The driver integrated circuit DIC may be mounted to the circuit board and electrically connected to the pads PD.

In some embodiments, the display area DA may have various shapes. The display area DA may have a closed loop shape including straight and/or curved sides. For example, the display area DA may have shapes such as a polygon, a circle, a semicircle, an ellipse, or the like.

In some embodiments, the display panel DP may have a flat display surface. In some embodiments, the display panel DP may have an at least partially round display surface. In some embodiments, the display panel DP may be bendable, foldable, or rollable display surface. For example, the display panel DP and/or the substrate SUB may include materials having a flexible material to enable these features.

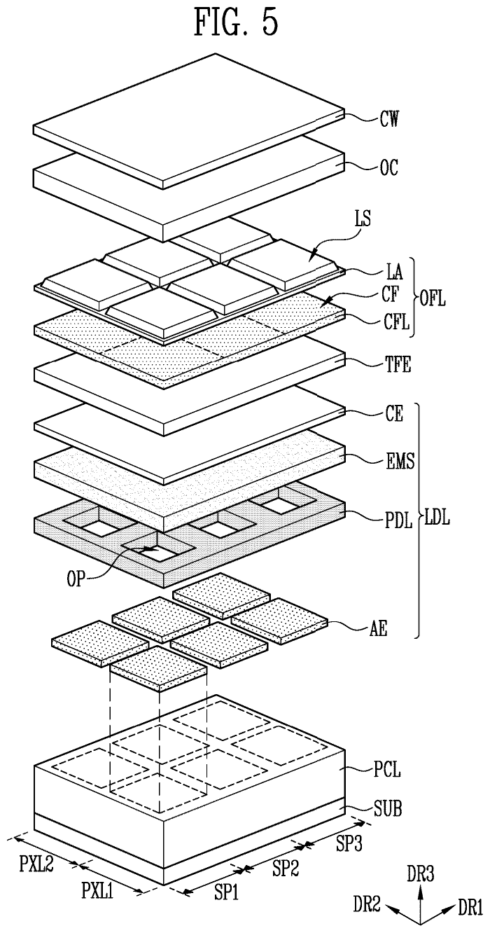

FIG. 5 is an example of an exploded perspective view of a portion of the display panel DP of FIG. 4. In FIG. 5, the portion of the display panel DP corresponding to two pixels PXL1 and PXL2 among the pixels PXL in FIG. 4 is schematically illustrated for clear and concise description. A portion of the display panel DP corresponding to the remaining pixels may be similarly configured.

Referring to FIGS. 4 and 5, each of first and second pixels PXL1 and PXL2 may include first to third sub-pixels SP1 to SP3. However, embodiments are not limited thereto. For example, each of the first and second pixels PXL1 and PXL2 may include two or more sub-pixels.

In FIG. 5, the first to third sub-pixels SP1 to SP3 are illustrated as having square shapes and having the same sizes as each other when viewed in a third direction DR3 intersecting the first and second directions DR1 and DR2. However, embodiments are not limited thereto. The first to third sub-pixels SP1 to SP3 may be modified to have various shapes.

The display panel DP may include the substrate SUB, a pixel circuit layer PCL, a light-emitting element layer LDL, a sealing layer TFE, an optical functional layer OFL, an overcoat layer OC, and a cover window CW. In one aspect, the light-emitting element layer LDL includes an anode electrodes AE, a pixel defining layer PDL, a light-emitting structure EMS, and the cathode electrode CE. In one aspect, the optical functional layer OFL includes a color filter layer CFL and a lens array LA.

In some embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be fabricated using a bulk wafer, an epitaxial layer, a silicon on insulator (SOI) layer, a semiconductor on insulator (SeOI) layer, or the like. In some embodiments, the substrate SUB may include a glass substrate. In some embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least some of the circuit elements, the wirings, or the like. The conductive patterns may include copper, but embodiments are not limited thereto.

The circuit elements may include the sub-pixel circuit SPC (described with reference to FIG. 2) of each of the first to third sub-pixels SP1 to SP3. The sub-pixel circuit SPC may include transistors and one or more capacitors. Each of the transistors may include a semiconductor portion including a source region, a drain region, a channel region, and a gate electrode overlapping the semiconductor portion.

In some embodiments, when the substrate SUB is provided as the silicon substrate, the semiconductor portion is included in the substrate SUB, and the gate electrode may be included in the pixel circuit layer PCL as the conductive pattern of the pixel circuit layer PCL. In some embodiments, when the substrate SUB is provided as the glass substrate or a PI substrate, the semiconductor portion and the gate electrode may be included in the pixel circuit layer PCL. Each capacitor may include electrodes spaced apart from each another. For example, each capacitor may include the electrodes spaced apart from each other in a plan view defined by the first and second directions DR1 and DR2. For example, each capacitor may include the electrodes spaced apart from each other in the third direction DR3 with the insulating layer therebetween.

The wirings of the pixel circuit layer PCL may include signal lines connected to each of the first to third sub-pixels SP1 to SP3. For example, each of the first to third sub-pixels SP1 to SP3 may be connected to the gate line, the light-emitting control line, the data line, or the like. The wirings may further include a wiring connected to the first power supply voltage node VDDN of FIG. 2. In addition, the wirings may further include a wiring connected to the second power supply voltage node VSSN of FIG. 2.

In one aspect, light-emitting device layer LDL may include the anode electrodes AE, a pixel defining layer PDL, a light-emitting structure EMS, and the cathode electrode CE. The anode electrodes AE may be disposed on the pixel circuit layer PCL. The anode electrodes AE may contact circuit elements of the pixel circuit layer PCL. The anode electrodes AE may include an opaque conductive material capable of reflecting light, but embodiments are not limited thereto.

The pixel defining layer PDL may be disposed on the anode electrodes AE. The pixel defining layer PDL may include an opening OP exposing a portion of each of the anode electrodes AE. The opening OP of the pixel defining layer PDL may be understood as light-emitting areas respectively corresponding to the first to third sub-pixels SP1 to SP3. In some cases, the size of the openings may be substantially the same as the size of the anode electrodes AE. However, embodiments are not limited thereto. In some cases, the size of the openings may be smaller than or larger than the size of the anode electrodes AE.

In some embodiments, the pixel defining layer PDL may include an inorganic material. The pixel defining layer PDL may include a plurality of stacked inorganic layers. For example, the pixel defining layer PDL may include silicon oxide (SiOx) and silicon nitride (SiNx). In some embodiments, the pixel defining layer PDL may include an organic material. However, the material of the pixel defining layer PDL is not limited thereto.

The light-emitting structure EMS may be disposed on the anode electrodes AE exposed by the opening OP of the pixel defining layer PDL. The light-emitting structure EMS may include a light-emitting layer configured to generate light, an electron transport layer configured to transport electrons, a hole transport layer configured to transmit holes, or the like.

In some embodiments, the light-emitting structure EMS may fill the opening OP of the pixel defining layer PDL, but may be disposed entirely on top of the pixel defining layer PDL. For example, the light-emitting structure EMS may extend over the first to third sub-pixels SP1 to SP3. At least some of the layers in the light-emitting structure EMS may break or bend at boundaries between the first to third sub-pixels SP1 to SP3. However, embodiments are not limited thereto. For example, portions of the light-emitting structure EMS corresponding to the first to third sub-pixels SP1 to SP3 may be separated from each other, and each of the first to third sub-pixels SP1 to SP3 may be disposed in the opening OP of the pixel defining layer PDL.

The cathode electrode CE may be disposed on the light-emitting structure EMS. The cathode electrode CE may extend over the first to third sub-pixels SP1 to SP3. The cathode electrode CE may be provided as a common electrode for the first to third sub-pixels SP1 to SP3.

The cathode electrode CE may be a thin metal layer having a thickness sufficient to transmit light emitted from the light-emitting structure EMS. The cathode electrode CE may include a metallic material or a transparent conductive material so as to have a relatively small thickness. In some embodiments, the cathode electrode CE may include at least one of a variety of transparent conductive materials, including indium tin oxide, indium zinc oxide, indium tin zinc oxide, aluminum zinc oxide, gallium zinc oxide, zinc tin oxide, or gallium tin oxide. In some embodiments, the cathode electrode CE may include at least one of silver (Ag), magnesium (Mg), and mixtures thereof. However, the material of the cathode electrode CE is not limited thereto.

One of the anode electrodes AE, a portion of the light-emitting structure EMS overlapping the anode electrode AE, and a portion of the cathode electrode CE overlapping the portion of the light-emitting structure EMS may be understood as forming one light-emitting element LD (refer to FIG. 2). For examples, the light-emitting elements of the first to third sub-pixels SP1 to SP3 may each include one anode electrode, a portion of the light-emitting structure EMS overlapping therewith, and a portion the cathode electrode CE overlapping therewith. In each of the first to third sub-pixels SP1 to SP3, the holes injected from the anode electrode AE and the electrons injected from the cathode electrode CE are transported into the light-emitting layer of the light-emitting structure EMS to form excitons, and light may be generated when the excitons transition from the excited state to the ground state. The luminance of light may be determined based on the amount of current flowing through the light-emitting layer. The wavelength range of the generated light may be determined based on the configuration of the light-emitting layer.

An encapsulation layer TFE is disposed on the cathode electrode CE. The encapsulation layer TFE may cover the light-emitting element layer LDL and/or the pixel circuit layer PCL. The encapsulation layer TFE may prevent oxygen and/or moisture or the like from penetrating into the light-emitting element layer LDL. In some embodiments, the encapsulation layer TFE may include a structure in which one or more inorganic layers and one or more organic layers are alternately stacked. For example, the inorganic layer may include silicon nitride, silicon oxide, silicon oxynitride (SiOxNy), or the like. For example, the organic layer may include an organic insulating material such as an acrylic resin, an epoxy resin, a phenol resin, a polyamide resin, a polyimide resin, an unsaturated polyester resin, a polyphenylenether resin, a polyphenylenesulfide resin, or benzocyclobutene (BCB). However, the materials of the organic layer and the inorganic layer of the encapsulation layer TFE are not limited thereto.

The encapsulation layer TFE may further include a thin layer including aluminum oxide (AlOx) configured to enhance the encapsulation efficiency of the encapsulation layer TFE. The thin layer including aluminum oxide may be located on an upper surface of the encapsulation layer TFE facing the optical functional layer OFL and/or on a lower surface of the encapsulation layer TFE facing the light-emitting element layer LDL. For example, the thin layer may be disposed between the encapsulation layer TFE and the light-emitting element layer LDL. Alternatively, the thin layer may be disposed between the encapsulation layer TFE and the optical functional layer OFL.

The thin layer including aluminum oxide may be formed by an atomic layer deposition (ALD) method. However, embodiments are not limited thereto. The encapsulation layer TFE may further include a thin layer including at least one of a variety of materials suitable for improving encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter the light emitted from the light-emitting structure EMS to selectively output light of a wavelength range or color corresponding to each sub-pixel. The color filter layer CFL may include color filters CF respectively corresponding to the first to third sub-pixels SP1 to SP3. For example, each of the color filters CF can pass light of the wavelength range corresponding to each sub-pixel. For example, the color filter CF corresponding to the first sub-pixel SP1 may pass red color light, the color filter corresponding to the second sub-pixel SP2 may pass green color light, and the color filter corresponding to the third sub-pixel SP3 may pass blue color light. At least a portion of the color filters CF may be omitted based on the light emitted from the light-emitting structure EMS of each sub-pixel.

The lens array LA may be disposed on the color filter layer CFL. The lens array LA may include lenses LS respectively corresponding to the first to third sub-pixels SP1 to SP3. Each of the lenses LS may output the light emitted from the light-emitting structure EMS in the intended path, thereby improving the light exit efficiency. The lens array LA may have a relatively high refractive index. For example, the lens array LA may have a higher refractive index than the overcoat layer OC. In some embodiments, the lenses LS may include an organic material. In some embodiments, the lenses LS may include an acrylic material. However, the material of the lenses LS is not limited thereto.

In some embodiments, at least some of the color filters CF of the color filter layer CFL and at least some of lenses LS of the lens array LA may be shifted in a direction parallel to the plane defined by the first and second directions DR1 and DR2 than the opening OP of the pixel defining layer PDL. For example, in a center region of the display area DA, a center of the color filter CF and a center of the lens LS may be aligned or overlapped with a center of the opening OP of the corresponding pixel defining layer PDL when viewed in the third direction DR3. For example, in the central region of the display area DA, the opening OP of the pixel defining layer PDL may completely overlap the corresponding color filter of the color filter layer CFL and the corresponding lens of the lens array LA. In a region adjacent to the non-display area NDA in the display area DA, the center of the color filter and the center of the lens may be shifted in a planar direction from the center of the opening OP of the corresponding pixel defining layer PDL when viewed in the third direction DR3. For example, in the region adjacent to the non-display region NDA in the display region DA, the opening OP of the pixel defining layer PDL may partially overlap the corresponding color filter of the color filter layer CFL and the corresponding lens of the lens array LA. Accordingly, in the center of the display area DA, the light emitted from the light-emitting structure EMS may be efficiently output in a normal direction of the display surface. The light emitted from the light-emitting structure EMS may be efficiently output in a direction inclined by a predetermined angle with respect to the normal direction of the display surface outside the display area DA.

The overcoat layer OC may be disposed on the lens array LA. The overcoat layer OC may cover the optical functional layer OFL, the encapsulation layer TFE, the light-emitting structure EMS, and/or the pixel circuit layer PCL. The overcoat layer OC may include a variety of materials suitable for protecting the underlying layers thereof from foreign matter such as dust, moisture, or the like. For example, the overcoat layer OC may include at least one of an inorganic insulating layer and an organic insulating layer. For example, the overcoat layer OC may include, but is not limited to, epoxy. The overcoat layer OC may have a lower refractive index than the lens array LA.

The cover window CW may be disposed on the overcoat layer OC. cover window CW is the outermost protective layer of the display panel DP. The cover window CW may protect the underlying layers thereof. The cover window CW may have a higher refractive index than the overcoat layer OC. The cover window CW may include glass, but embodiments are not limited thereto. For example, the cover window CW may be an encapsulation glass which protects components disposed underneath. In some embodiments, the cover window CW may be omitted.

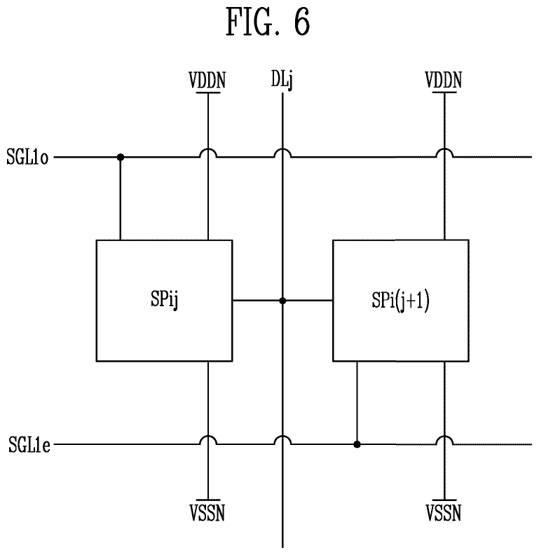

FIG. 6 is a block diagram illustrating sub-pixels sharing a data line according to an embodiment of the present disclosure. Referring to FIG. 6, a j-th sub-pixel SPij arranged in the i-th row and the j-th column and a (j+1)-th sub-pixel SPi(j+1) arranged in the i-th row and the (j+1)-th column are illustrated. The j-th sub-pixel SPij and the (j+1)-th sub-pixel SPi(j+1) may include the sub-pixel circuit SPC and the light-emitting element LD illustrated in FIG. 3.

The j-th sub-pixel SPij and the (j+1)-th sub-pixel SPi(j+1) may be connected to the same data line DLj. For example, the j-th sub-pixel SPij and the (j+1)-th sub-pixel SPi(j+1) may share one data line DLj. The j-th sub-pixel SPij and the (j+1)-th sub-pixel SPi(j+1) may be symmetrical arranged to each other with respect to the data line DLj.

A pair of sub-pixels SPij and SPi(j+1) may emit light based on a data signal supplied to the data line DLj. As the pair of sub-pixels SPij and SPi(j+1) share one data line DLj, the frequency of charging the data voltage may be reduced compared to the case where the data line DLj is not shared. As a result, the dynamic power of the display device may be reduced.

The j-th sub-pixel SPij may be connected to a first odd-numbered gate line SGL10, and the (j+1)-th sub-pixel SPi(j+1) may be connected to a first even-numbered gate line SGL1e. The first odd-numbered gate line SGL1o and the first even-numbered gate line SGL1e may correspond to the first sub-gate line SGL1 in FIG. 3.

The first odd-numbered gate line SGL1o may be connected to a sub-pixel disposed in an odd-numbered column, and the first even-numbered gate line SGL1e may be connected to a sub-pixel disposed in an even-numbered column. However, the present disclosure is not limited thereto, and the first odd-numbered gate line SGL1o may be connected to a sub-pixel disposed in the even-numbered column, and the first even-numbered gate line SGL1e may be connected to a sub-pixel disposed in the odd-numbered column.

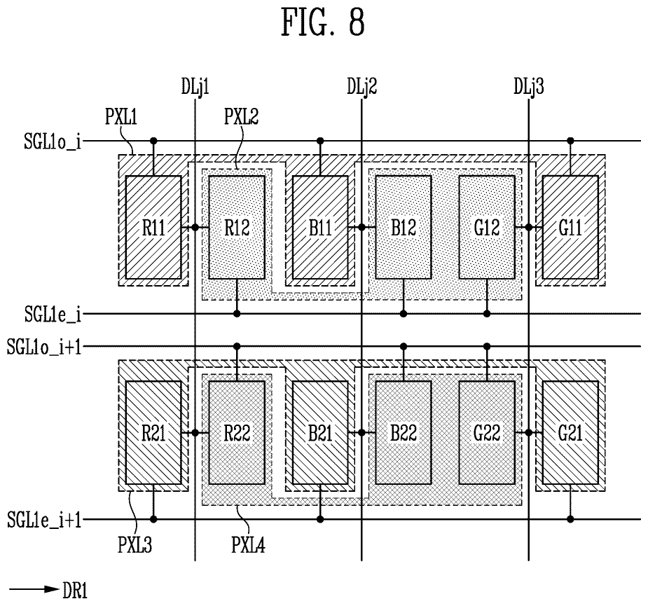

In addition, in an odd-numbered row, the first odd-numbered gate line SGL1o may be connected to a sub-pixel disposed in the odd-numbered column, and in an even-numbered row the first odd-numbered gate line SSGL1o may also be connected to a sub-pixel disposed in the even-numbered column. In the odd-numbered row, the first even-numbered gate line SGL1e may be connected to a sub-pixel disposed in the even-numbered column, and in the even-numbered row, the first even-numbered gate line SGL1e may be connected to a sub-pixel arranged in the odd-numbered column. Further detail on the arrangement of the gate line is described with reference to FIG. 8.

According to some embodiments, the connection relationship of the first sub-gate lines SGL1o and SGL1e may be changed. In some embodiments, when the gate driver 120 of FIG. 1 applies a first sub-gate signal having the turn-on level to the first odd-numbered gate line SGL10, the second transistor T2 of the j-th sub-pixel SPij is turned on, so that the data signal may be applied from the data line DLj to the j-th sub-pixel SPij.

In some cases, when the gate driver 120 of FIG. 1 applies a first sub-gate signal having the turn-on level to the first even-numbered gate line SGL1e, the second transistor T2 of the (j+1)-th sub-pixel SPi(j+1) is turned on, so that the data signal may be applied from the data line DLj to the (j+1)-th sub-pixel SPi(j+1).

For example, the gate driver 120 of FIG. 1 may apply the first sub-gate signal having the turn-on level to the first odd-numbered gate line SGL1o during a first period. During the first period, the data driver 130 may provide a data signal with a corresponding data voltage to the j-th sub-pixel SPij to the data line DLj.

In addition, the gate driver 120 may apply the first sub-gate signal having the turn-on level to the first even-numbered gate line SGL1e during a second period after the first period. During the second period, and the data driver 130 may provide a data signal having a corresponding data voltage to the (j+1)-th sub-pixel SPi(j+1) to the data line DLj.

In some embodiments, the j-th sub-pixel SPij and the (j+1)-th sub-pixel SPi(j+1) may generate light of the same color. For example, the j-th sub-pixel SPij and the (j+1)-th sub-pixel SPi(j+1) may generate red light.

Although the j-th sub-pixel SPij and the (j+1)-th sub-pixel SPi(j+1) are described as an example in FIG. 6, this is for convenience of description. The sub-pixels disposed in the display panel may be disposed as in the j-th and (j+1)-th sub-pixels SPij and SPi(j+1). For example, the sub-pixels that generate light of the same color and are placed in adjacent columns may share the data line DLj.

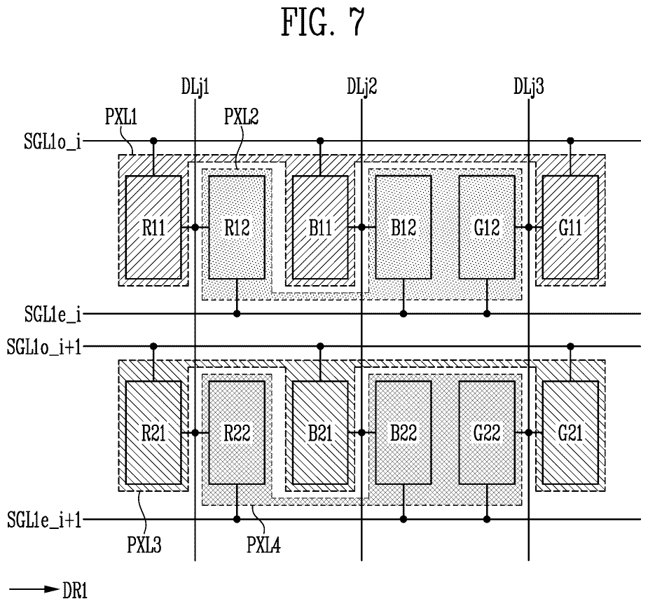

FIG. 7 is a block diagram illustrating a pixel including sub-pixels sharing a data line according to an embodiment of the present disclosure.

Referring to FIG. 7, the example shown includes the first pixel PXL1, the second pixel PXL2, a third pixel PXL3, and a fourth pixel PXL4.

The first pixel PXL1 and the second pixel PXL2 may be disposed in the i-th row, and the third pixel PXL3 and the fourth pixel PXL4 may be disposed in an (i+1)-th row. The second pixel PXL2 may be adjacent to the first pixel PXL1, and the fourth pixel PXL4 may be adjacent to a third pixel PXL3. In some cases, the first pixel PXL1 and the third pixel PXL3 may be disposed in the same column, and the second pixel PXL2 and the fourth pixel PXL4 may be disposed in the same column.

Each of the first to fourth pixels PXL1 to PXL4 may include three sub-pixels. The first pixel PXL1 may include a first sub-pixel R11, a second sub-pixel B11, and a third sub-pixel G11. The second pixel PXL2 may include a first sub-pixel R12, a second sub-pixel B12, and a third sub-pixel G12. The third pixel PXL3 may include a first sub-pixel R21, a second sub-pixel B21, and a third sub-pixel G21. The fourth pixel PXL4 may include a first sub-pixel R22, a second sub-pixel B22, and a third sub-pixel G22.

Each of the sub-pixels of each of the first to fourth pixels PXL1 to PXL4 may include the sub-pixel circuit SPC and the light-emitting element LD illustrated in FIG. 3. Each of the sub-pixels illustrated in FIG. 7 may correspond to the j-th sub-pixel SPij or the (j+1)-th sub-pixel SPi(j+1) illustrated in FIG. 6. For example, the first sub-pixel R11 of the first pixel PXL1 may correspond to the j-th sub-pixel SPij, and the first sub-pixel R12 of the second pixel PXL2 may correspond to the (j+1)-th sub-pixel SPi(j+1). Accordingly, for convenience of description, a description overlapping with FIG. 6 may be omitted.

The first sub-pixels R11, R12, R21, and R22 may generate red color light, the second sub-pixels B11, B12, B21, and B22 may generate blue color light, and the third sub-pixels G11, G12, G21, and G22 may generate green color light.

In some embodiments, the second sub-pixels B11, B12, B21, and B22 may be disposed between the first sub-pixels R11, R12, R21, and R22 and the third sub-pixels G11, G12, G21, and G22. In some cases, the sub-pixels that emit the same color light are grouped in a matrix form. For example, the first sub-pixels R11, R12, R21, and R22 generating red color light are grouped in a quadrant, the second sub-pixels B11, B12, B21, and B22 generating blue light are grouped in a quadrant, and the third sub-pixels G11, G12, G21, and G22 generating green color light are grouped in a quadrant. The sub-pixels that generate blue light are disposed between the sub-pixels that generate red light and the sub-pixels that generate green light.

Referring to the i-th row, the first sub-pixel R11 of the first pixel PXL1, the first sub-pixel R12 of the second pixel PXL2, the second sub-pixel B11 of the first pixel PXL1, the second sub-pixel B12 of the second pixel PXL2, the third sub-pixel G12 of the second pixel PXL2, and the third sub-pixel G11 of the first pixel PXL1 may be disposed sequentially in the first direction DR1. Referring to the (i+1)-th row, the first sub-pixel R21 of the third pixel PXL3, the first sub-pixel R22 of the fourth pixel PXL4, the second sub-pixel B21 of the third pixel PXL3, the second sub-pixel B22 of the fourth pixel PXL4, the third sub-pixel G22 of the fourth pixel PXL4, and the third sub-pixel G21 of the third pixel PXL3 may be disposed sequentially in the first direction DR1.

For example, in the first direction DR1, sub-pixels generating red color light, sub-pixels generating blue color light, and sub-pixels generating green color light may be sequentially disposed.

In one row, the arrangement order between the first sub-pixels R11, R12, R21, and R22 may be the same as the arrangement order between second sub-pixels B11, B12, B21, and B22. For example, in the case of the first sub-pixels R11 and R12 disposed in the i-th row, the first sub-pixel R11 of the first pixel PXL1 and the first sub-pixel R12 of the second pixel PXL2 may be sequentially disposed in the first direction DR1.

In addition, in the case of the second sub-pixels B11 and B12 disposed in the i-th row, the second sub-pixel B11 of the first pixel PXL1 and the second sub-pixel B12 of the second pixel PXL2 may be sequentially disposed in the first direction DR1. For example, in the case of the first sub-pixels R11 and R12 and the second sub-pixels B11 and B12, the first pixel PXL1 and the second pixel PXL2 may be sequentially disposed in the first direction DR1.

However, in one row, the arrangement order between the first sub-pixels R11, R12, R21, and R22 and the arrangement order between the third sub-pixels G11, G12, G21, and G22 may be different. For example, in the case of the first sub-pixels R11 and R12 disposed in the i-th row, the first sub-pixel R11 of the first pixel PXL1 and the first sub-pixel R12 of the second pixel PXL2 may be sequentially disposed in the first direction DR1.

On the other hand, in the case of the third sub-pixels G11 and G12 disposed in the i-th row, the third sub-pixel G12 of the second pixel PXL2 and the third sub-pixel G11 of the first pixel PXL1 may be sequentially disposed in the first direction DR1.

For example, the first sub-pixels R11 and R12 may be disposed in the order of the first pixel PXL1 and the second pixel PXL2 in the first direction DR1, while the third sub-pixels G11 and G12 may be disposed in the order of the second pixel PXL2 and the first pixel PXL1 in the first direction DR1. Accordingly, this configuration of the sub-pixels ensures that the wirings between the gate lines SGL and the sub-pixels are not twisted.

The first sub-pixels R11, R12, R21, and R22 may share a first data line DLj1, the second sub-pixels B11, B12, B21, and B22 may share a second data line DLj2, and the third sub-pixels G11, G12, G21, and G22 may share a third data line DLj3.

For example, the first sub-pixels R11 and R12 may be symmetrical arranged to each other with respect to the first data line DLj1, and the first sub-pixels R21 and R22 may be symmetrical arranged to each other with respect to the first data line DLj1. The second sub-pixels B11 and B12 may be symmetrical arranged to each other with respect to the second data line DLj2, and the second sub-pixel B21 and B22 may be symmetrical arranged to each other with respect to the second data line DLj2. The third sub-pixels G11 and G12 may be symmetrical arranged to each other with respect to the third data line DLj3, and the third sub-pixels G21 and G22 may be symmetrical arranged to each other with respect to the third data line DLj3.

The first pixel PXL1 may be connected to a first odd-numbered gate line SGL1o_i, and the second pixel PXL2 may be connected to a first even-numbered gate line SGL1e_i. For example, the pixels disposed in the i-th row may be alternately connected to the first odd-numbered gate line SGL1o_i and the first even-numbered gate line SGL1e_i. The first odd-numbered gate line SGL1o_i and the first even-numbered gate line SGL1e_i may correspond to the first sub-gate line SGL1 of FIG. 3. In some cases, the first sub-pixels R11, second sub-pixels B11, and the third sub-pixels G11 of the first pixel PXL1 are connected to the first odd-numbered gate line SGL1o_i. The first sub-pixels R12, second sub-pixels B12, and the third sub-pixels G12 of the second pixel PXL2 are connected to the first even-numbered gate line SGL1e_i. Accordingly, referring to the first sub-pixels R11, R12, R21, and R22, the first odd-numbered gate line and the first even-numbered gate line may be connected with the first sub-pixels R11, R12, R21, and R22 in a zigzag form.

In some embodiments, when the gate driver 120 of FIG. 1 applies a first sub-gate signal having the turn-on level to the first odd-numbered gate line SGL1o_i, the second transistor T2 of the first sub-pixel R11 is turned on, so that the data signal may be applied from the first data line DLj1 to the first sub-pixel R11.

In addition, when the gate driver 120 of FIG. 1 applies a first sub-gate signal having the turn-on level to the first even-numbered gate line SGL1e_i, the second transistor T2 of the first sub-pixel R12 is turned on, so that the data signal may be applied from the first data line DLj1 to the first sub-pixel R12.

Similar to the first sub-pixels R11 and R12, the data signal may be applied to the second sub-pixels B11 and B12 and to the third sub-pixels G11 and G12 through the second data line DLj2 and the third data line DLj3, respectively.

The third pixel PXL3 may be connected to a first odd-numbered gate line SGL1o_i+1, and the fourth pixel PXL4 may be connected to a first even-numbered gate line SGL1e_i+1. For example, the pixels disposed in the (i+1)-th row may be alternately connected to the first odd-numbered gate line SGL1o_i+1 and the first even-numbered gate line SGL1e_i+1. The first odd-numbered gate line SGL1o_i+1 and the first even-numbered gate line SGL1e_i+1 may correspond to the first sub-gate line SGL1 of FIG. 3.

In some embodiments, when the gate driver 120 of FIG. 1 applies a first sub-gate signal having the turn-on level to the first odd-numbered gate line SGL1o_i+1, the second transistor T2 of the first sub-pixel R21 is turned on, so that the data signal may be applied from the first data line DLj1 to the first sub-pixel R21 of the third pixel PXL3. In addition, when the gate driver 120 of FIG. 1 applies a first sub-gate signal having the turn-on level to the first even-numbered gate line SGL1e_i+1, the second transistor T2 of the first sub-pixel R22 is turned on, so that the data signal may be applied from the first data line DLj1 to the first sub-pixel R22 of the fourth pixel PXL4. Similar to the first sub-pixels R21 and R22, the data signal may be applied to the second sub-pixels B21 and B22 and to the third sub-pixels G21 and G22 through the second data line DLj2 and the third data line DLj3, respectively.

In some embodiments, the gate driver 120 of FIG. 1 may apply the first sub-gate signal having the turn-on level to the first odd-numbered gate line SGL1o_i during the first period, and the data driver 130 may provide the data signal having the corresponding data voltage to the first sub-pixel R11 to the first data line DLj1 during the first period.

During the second period after the first period, the gate driver 120 may apply the first sub-gate signal having the turn-on level to the first even-numbered gate line SGL1e_i, and during the second period, the data driver 130 may provide the data signal having the corresponding data voltage to the first sub-pixel R12 to the first data line DLj1.

During a third period after the second period, the gate driver 120 may apply the first sub-gate signal having the turn-on level to the first odd-numbered gate line SGL1o_i+1, and during the third period, the data driver 130 may provide the data signal the data voltage corresponding to the first sub-pixel R21 to the first data line DLj1.

During a fourth period after the third period, the gate driver 120 may apply the first sub-gate signal having the turn-on level to the first even-numbered gate line SGL1e_i+1, and during the fourth period, the data driver 130 may provide the data signal having the data voltage corresponding to the first sub-pixel R22 to the first data line DLj1.

For example, the data signal may be provided in the order of the first sub-pixel R11 of the first pixel PXL1, the first sub-pixel R12 of the second pixel PXL2, the first sub-pixel R21 of the third pixel PXL3, and the first sub-pixel R22 of the fourth pixel PXL4. As the sub-pixels generating light of the same color share a data line with each other, the dynamic power of the display device may be reduced.

FIG. 8 is a block diagram illustrating the pixel including the sub-pixels sharing the data line according to an embodiment of the present disclosure. Referring to FIG. 8, the example shown includes the first pixel PXL1, the second pixel PXL2, the third pixel PXL3, and the fourth pixel PXL4. The first pixel PXL1, the second pixel PXL2, the third pixel PXL3, and the fourth pixel PXL4 in FIG. 8 may correspond to the first pixel PXL1, the second pixel PXL2, the third pixel PXL3, and the fourth pixel PXL4 in FIG. 7. Accordingly, for convenience of description, a description overlapping with FIG. 7 may be omitted.

The first sub-pixels R11, R12, R21, and R22 may share the first data line DLj1, the second sub-pixels B11, B12, B21, and B22 may share the second data line DLj2, and the third sub-pixels G11, G12, G21, and G22 may share the third data line DLj3.

The first pixel PXL1 may be connected to the first odd-numbered gate line SGL1o_i, and the second pixel PXL2 may be connected to the first even-numbered gate line SGL1e_i. For example, the pixels disposed in the i-th row may be alternately connected to the first odd-numbered gate line SGL1o_i and the first even-numbered gate line SGL1e_i. The first odd-numbered gate line SGL1o i and the first even-numbered gate line SGL1e_i may correspond to the first sub-gate line SGL1 of FIG. 3. In some cases, the wiring connection between the first pixel PXL1 and the first odd-numbered gate line SGL1o_i may be substantially the same as the wiring connection described with reference to FIG. 7. Similarly, the wiring connection between the second pixel PXL2 and the first even-numbered gate line SGL1e_i may be substantially the same as the wiring connection described with reference to FIG. 7.

In some embodiments, when the gate driver 120 of FIG. 1 applies the first sub-gate signal having the turn-on level to the first odd-numbered gate line SGL1o_i, the second transistor T2 of the first sub-pixel R11 is turned on, so that the data signal may be applied from the first data line DLj1 to the first sub-pixel R11. In addition, when the gate driver 120 of FIG. 1 applies the first sub-gate signal having the turn-on level to the first even-numbered gate line SGL1e i, the second transistor T2 of the first sub-pixel R12 is turned on, so that the data signal may be applied from the first data line DLj1 to the first sub-pixel R12.

Similar to the first sub-pixels R11 and R12, the data signal may be applied to the second sub-pixels B11 and B12 and to the third sub-pixels G11 and G12 through the second data line DLj2 and the third data line DLj3, respectively.

The third pixel PXL3 may be connected to the first even-numbered gate line SGL1e_i+1, and the fourth pixel PXL4 may be connected to the first odd-numbered gate line SGL1o_i+1. For example, the pixels disposed in the (i+1)-th row may be alternately connected to the first even-numbered gate line SGL1e_i+1 and the first odd-numbered gate line SGL1o_i+1. The first odd-numbered gate line SGL1o_i+1 and the first even-numbered gate line SGL1e_i+1 may correspond to the first sub-gate line SGL1 of FIG. 3. Compared to the embodiment shown in FIG. 7, the third pixel PXL3 may be connected to the first even-numbered gate line SGL1e_i+1 (whereas the third pixel PXL3 is connected to the first odd-numbered gate line SGL1o_i+1 in FIG. 7), and the fourth pixel PXL4 is connected to the first odd-numbered gate line SGL1o_i+1 (whereas the fourth pixel PXL4 is connected to the first even-numbered gate line SGL1e_i+1 in FIG. 7).

In some embodiments, when the gate driver 120 of FIG. 1 applies the first sub-gate signal having the turn-on level to the first even-numbered gate line SGL1e_i+1, the second transistor T2 of the first sub-pixel R21 of third pixel PXL3 is turned on, so that the data signal may be applied from the first data line DLj1 to the first sub-pixel R21 of third pixel PXL3. In addition, when the gate driver 120 of FIG. 1 applies the first sub-gate signal having the turn-on level to the first odd-numbered gate line SGL1o_i+1, the second transistor T2 of the first sub-pixel R22 of the fourth pixel PXL4 is turned on, so that the data signal may be applied from the first data line DLj1 to the first sub-pixel R22 of the fourth pixel PXL4.

Similar to the first sub-pixels R21 and R22, the data signal may be applied to the second sub-pixels B21 and B22 and to the third sub-pixels G21 and G22 through the second data line DLj2 and the third data line DLj3, respectively.

The pixels PXL1 and PXL2 disposed in the i-th row are alternately connected in an order of the first odd-numbered gate line SGL1o_i+1 and the first even-numbered gate line SGL1e_i+1, and the pixels PXL3 and PXL4 disposed in the (i+1)-th row may be alternately connected in an order of the first even-numbered gate line SSGL1e_i+1 and the second odd-numbered gate line SGL1o i+1.

In some embodiments, the gate driver 120 of FIG. 1 may apply the first sub-gate signal having the turn-on level to the first odd-numbered gate line SGL1o_i during the first period, and the data driver 130 may provide the data signal having the data voltage corresponding to the first sub-pixel R11 of the first pixel PXL1 to the first data line DLj1 during the first period.

During the second period after the first period, the gate driver 120 may apply the first sub-gate signal having the turn-on level to the first even-numbered gate line SGL1e_i, and during the second period, the data driver 130 may provide the data signal having the data voltage corresponding to the first sub-pixel R12 of the second pixel PXL2 to the first data line DLj1.

During the third period after the second period, the gate driver 120 may apply the first sub-gate signal having the turn-on level to the first odd-numbered gate line SGL1o_i+1, and during the third period, the data driver 130 may provide the data signal having the data voltage corresponding to the first sub-pixel R22 of the fourth pixel PXL4 to the first data line DLj1.

During the fourth period that is after the third period, the gate driver 120 may apply the first sub-gate signal having the turn-on level to the first even-numbered gate line SGL1e_i+1, and during the fourth period, the data driver 130 may provide the data signal having the data voltage corresponding to the first sub-pixel R21 of the third pixel PXL3 to the first data line DLj1.

For example, the data signal may be provided in an order of the first sub-pixel R11 of the first pixel PXL1, the first sub-pixel R12 of the second pixel PXL2, the first sub-pixel R22 of the fourth pixel PXL4, and the first sub-pixel R21 of the third pixel PXL3.

As the sub-pixels generating light of the same color share a data line and data signals are continuously provided to the first sub-pixel R12 of the second pixel PXL2 and the first sub-pixel R22 of the fourth pixel PXL4 in the same column, the power consumption of the display device may be reduced.

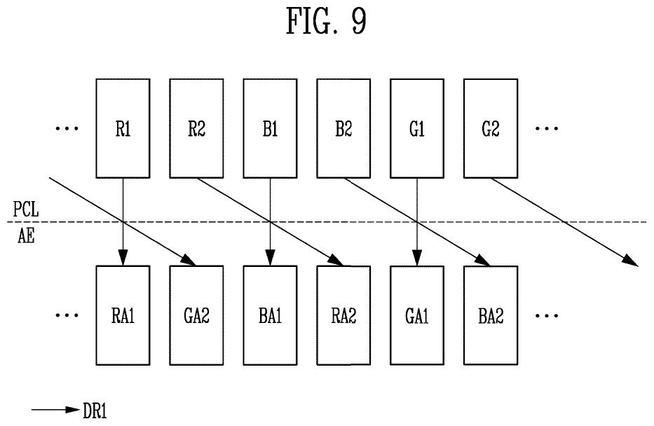

FIG. 9 is a diagram illustrating a connection relationship between the pixel circuit layer PCL and the anode electrode AE according to an embodiment of the present disclosure.

Referring to FIG. 9, the sub-pixel circuit SPC and the anode electrode AE of the first sub-pixels R11 and R12, the second sub-pixels B11 and B12, and the third sub-pixels G11 and G12 of FIGS. 7 and 8 are illustrated.

Each of first sub-pixel circuits R1 and R2, second sub-pixel circuits B1 and B2, and third sub-pixel circuits G1 and G2 respectively corresponds to the first sub-pixels R11 and R12, the second sub-pixels B11 and B12, and the third sub-pixels G11 and G12 disposed in the i-th row illustrated in FIGS. 7 and 8.

For example, the first sub-pixel circuit R1 is a sub-pixel circuit of the first sub-pixel R11 of the first pixel PXL1, the first sub-pixel circuit R2 is a sub-pixel circuit of the first sub-pixel R12 of the second pixel PXL2, the second sub-pixel circuit B1 is a sub-pixel circuit of the second sub-pixel B11 of the first pixel PXL1, the second sub-pixel circuit B2 is a sub-pixel circuit of the second sub-pixel B12 of the second pixel PXL2, the third sub-pixel circuit G1 is a sub-pixel circuit of the third sub-pixel G11 of the first pixel PXL1, and the third sub-pixel circuit G2 is a sub-pixel circuit of the third sub-pixel G12 of the second pixel PXL2.

Accordingly, the sub-pixel circuits of the first sub-pixels R1 and R2 may share the same data line, the sub-pixel circuits of the second sub-pixels B1 and B2 may share the same data line, and the sub-pixel circuits of the third sub-pixels G1 and G2 may share the same data line.

Since the arrangement order of the first sub-pixel circuits R1 and R2, the second sub-pixel circuits B1 and B2, and the third sub-pixel circuits G1 and G2 corresponds to the arrangement order of first sub-pixels R11 and R12, the second sub-pixels B11 and B12, and the third sub-pixels G11 and G12 illustrated in FIGS. 7 and 8, overlapping description is omitted.

The first sub-pixel circuits R1 and R2, the second sub-pixel circuits B1 and B2, and the third sub-pixel circuits G1 and G2 may be disposed in the pixel circuit layer PCL of FIG. 5. A first anode electrode RA1 is an anode electrode of the first sub-pixel R11, a first anode electrode RA2 is an anode electrode for the first sub-pixel R12, a second anode electrode BA1 is an anode electrode for the second sub-pixel B11, a second anode electrode BA2 is an anode electrode for the second sub-pixel B12, a third anode electrode GA1 is an anode electrode for the third sub-pixel G11, and a third anode electrode GA2 is an anode electrode for the third sub-pixel G12.

The first anode electrode RA1 of the first pixel PXL1, the third anode electrode GA2 of the second pixel PXL2, the second anode electrode BA1 of the first pixel PXL1, the first anode electrode RA2 of the second pixel PXL2, the third anode electrode GA1 of the first pixel PXL1, and the second anode electrode BA2 of the second pixel PXL2 may be sequentially disposed in the first direction DR1.

The first anode electrodes RA1 and RA2, the second anode electrodes BA1 and BA2, and the third anode electrodes GA1 and GA2 may correspond to the anode electrodes AE of FIG. 5. For example, the first anode electrodes RA1 and RA2, the second anode electrodes BA1 and BA2, and the third anode electrodes GA1 and GA2 may be included in the light-emitting element layer LDL of FIG. 5.

The first sub-pixel circuit R1, the second sub-pixel circuit B1, and the third sub-pixel circuit G2 may be disposed to overlap the corresponding anode electrodes RA1, BA1, and GA2 in a plan view. However, the first sub-pixel circuit R2, the second sub-pixel circuit B2, and the third sub-pixel circuit G1 may not overlap the corresponding anode electrodes RA2, BA2, and GA1 in a plan view.

Accordingly, a wiring electrically connecting the first sub-pixel circuit R2 and the first anode electrode RA2, a wiring electrically connecting the second sub-pixel circuit B2 and the second anode electrode BA2, and a wiring electrically connecting the third sub-pixel circuit G2 and the third anode electrode GA2 may be disposed to extend in the first direction DR1.

As the wiring electrically connecting the first sub-pixel circuit R2 and the first anode electrode RA2, the wiring electrically connecting the second sub-pixel circuit B2 and the second anode electrode BA2, and the wiring electrically connecting the third sub-pixel circuit G2 and the third anode electrode GA2, the anode electrodes and the sub-pixel circuits may be implemented without crossing or twisting the wirings.

In addition, as the anode electrodes and the sub-pixel circuits are implemented without crossing or twisting, the wiring electrically connecting the first sub-pixel circuit R2 and the first anode electrode RA2, the wiring electrically connecting the second sub-pixel circuit B2 and the second anode electrode BA2, and the wiring electrically connecting the third sub-pixel circuit G2 and the third anode electrode GA2 may experience reduced parasitic capacitance.

Parasitic capacitance is unintended capacitance that occurs between parts of an electrical component or circuits based on the proximity. In some cases, the parasitic capacitance occurs when wirings or circuits cross or twist. Embodiments of the present invention minimizes parasitic capacitance by preventing wire twisting and overlapping, which minimizes unwanted charge storage and signal interference. By using the wiring configuration illustrated in FIG. 9, voltage in the first capacitor C1 and first transistor T1 can be maintained, leading to consistent brightness and stable color representation across the display panel. Additionally, by maintaining uniform signal paths, embodiments of the present disclosure enhance response time and lowers power consumption, enhancing overall display efficiency and refresh rates.

The parasitic capacitance may cause the variations in the voltage stored in the first capacitor C1 between the third node N3 and the second node N2 illustrated in FIG. 3, which results in a variation in the luminance and color output of the light emitted by the sub-pixels SPij.

As the parasitic capacitance decreases, the voltage holding ratio between the third node N3 and the second node N2 may increase, from the standpoint of the first transistor T1 in FIG. 3. For example, the change in the voltage stored in the first capacitor C1 may be reduced by the parasitic capacitance. Accordingly, each of the sub-pixels SPij including the first transistor T1 may output light whose data voltage applied through the data line DLj has a target brightness and color. As a result, the luminance and color variation between the sub-pixel SPij may be reduced.

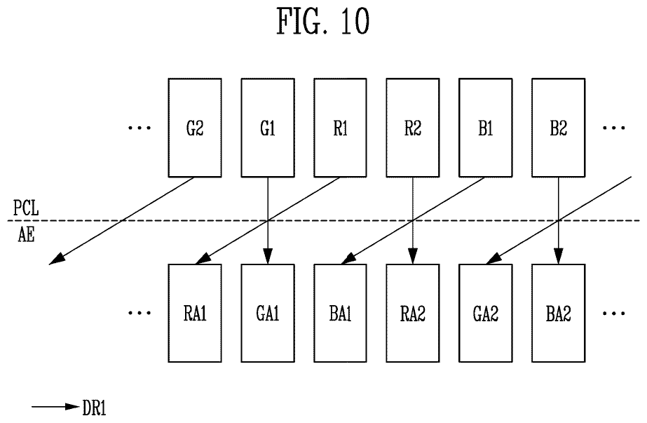

FIG. 10 is a diagram illustrating the connection relationship between the pixel circuit layer PCL and the anode electrode AE according to an embodiment of the present disclosure.

Referring to FIG. 10, the sub-pixel circuit SPC and the anode electrode AE of the first sub-pixels R11 and R12, the second sub-pixels B11 and B12, and the third sub-pixels G11 and G12 of FIGS. 7 and 8 are illustrated.

The first sub-pixel circuits R1 and R2, the second sub-pixel circuits B1 and B2, and the third sub-pixel circuits G1 and G2 of FIG. 10 are similar to the first sub-pixel circuits R1 and R2, and the second sub-pixel circuits B1 and B2, and the third sub-pixel circuits G1 and G2 of FIG. 9, and thus overlapping descriptions thereof will be omitted.

The first anode electrodes RA1 and RA2, the second anode electrodes BA1 and BA2, and the third anode electrodes GA1 and GA2 of FIG. 10 are similar to the first anode electrodes RA1 and RA2, the second anode electrodes BA1 and BA2, and the third anode electrodes GA1 and GA2 of FIG. 9, and thus overlapping descriptions thereof will be omitted.

Each of the first sub-pixel circuits R1 and R2, the second sub-pixel circuits B1 and B2, and the third sub-pixel circuits G1 and G2 corresponds to the first sub-pixels R11 and R12, the second sub-pixels B11 and B12, and the third sub-pixels G11 and G12 disposed in the i-th row illustrated in FIGS. 7 and 8.

For example, the first sub-pixel circuit R1 is the sub-pixel circuit of the first sub-pixel R11 of the first pixel PXL1, the first sub-pixel circuit R2 is the sub-pixel circuit of the first sub-pixel R12 of the second pixel PXL2, the second sub-pixel circuit B1 is the sub-pixel circuit of the second sub-pixel B11 of the first pixel PXL1, the second sub-pixel circuit B2 is the sub-pixel circuit of the second sub-pixel B12 of the second pixel PXL2, the third sub-pixel circuit G1 is the sub-pixel circuit of the third sub-pixel G11 of the first pixel PXL1, and the third sub-pixel circuit G2 is the sub-pixel circuit of the third sub-pixel G12 of the second pixel PXL2.

Referring to FIG. 10, the third sub-pixel circuit G2 of the second pixel PXL2, the third sub-pixel circuit G1 of the first pixel PXL1, the first sub-pixel circuit R1 of the first pixel PXL1, the first sub-pixel circuit R2 of the second pixel PXL2, the second sub-pixel circuit B1 of the first pixel PXL1, and the second sub-pixel circuit B2 of the second pixel PXL2 may be disposed sequentially in the first direction DR1. In some cases, the pattern of the sub-pixel circuits continues in the first direction DR1.

Similar to those described in FIG. 7, the second sub-pixels B11 and B12 may be disposed between the first sub-pixels R11 and R12 and the third sub-pixels G11 and G12. In addition, similar to those described in FIG. 7, the order in which the first sub-pixels R11 and R12 are disposed and the order in which the second sub-pixels B11 and B12 are disposed in one row may be the same, and the order in which the first sub-pixels R11 and R12 are disposed and the order in which the third sub-pixels G11 and G12 are disposed may be different.

The third sub-pixel circuit G1, the first sub-pixel circuit R2, and the second sub-pixel circuit B2 may be disposed to overlap the corresponding anode electrodes GA1, RA2, and BA2 in a plan view. However, the third sub-pixel circuit G2, the first sub-pixel circuit R1, and the second sub-pixel circuit B1 may not overlap the corresponding anode electrodes GA2, RA1, and BA1 in a plan view.

Accordingly, a wiring electrically connecting the third sub-pixel circuit G2 and the third anode electrode GA2, a wiring electrically connecting the first sub-pixel circuit R1 and the first anode electrode RA1, and a wiring electrically connecting the second sub-pixel circuit B1 and the second anode electrode BA1 may be disposed to extend in a direction opposite to the first direction DR1. For example, the wiring configuration between the sub-pixel circuits and the anode electrodes illustrated in FIG. 10 are opposite from the wiring configuration between the sub-pixel circuits and the anode electrodes illustrated in FIG. 9. Further detail is described below.

As the wiring electrically connecting the third sub-pixel circuit G2 and the third anode electrode GA2, the wiring electrically connecting the first sub-pixel circuit R1 and the first anode electrode RA1, and the wiring electrically connecting the second sub-pixel circuit B1 and the second anode electrode BA extend along the opposite direction of the first direction DR1, the anode electrodes and the sub-pixel circuits may be implemented without twisting the wirings. Accordingly, the wiring configuration illustrated in FIG. 10 minimizes parasitic capacitance by preventing wire twisting or crossings.

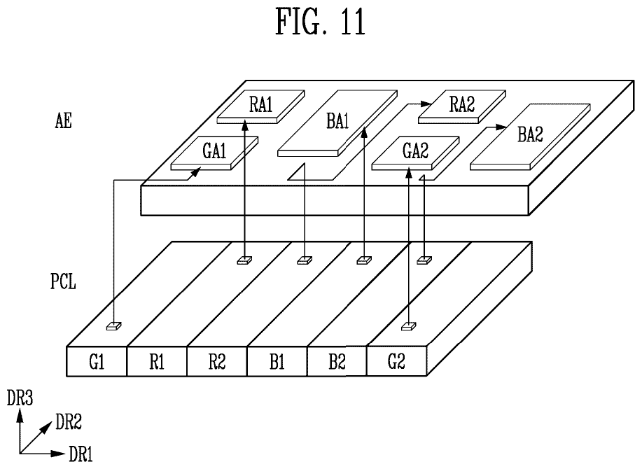

FIG. 11 is a perspective view illustrating the connection relationship between the pixel circuit layer PCL and the anode electrode AE according to an embodiment of the present disclosure.

Referring to FIG. 11, the third sub-pixel circuit G1 of the first pixel PXL1, the first sub-pixel circuit R1 of the first pixel PXL1, the first sub-pixel circuit R2 of the second pixel PXL2, the second sub-pixel circuit B1 of the first pixel PXL1, the second sub-pixel circuit B2 of the second pixel PXL2, and the third sub-pixel circuit G2 of the second pixel PXL2 may be sequentially disposed in the pixel circuit layer PCL in the first direction DR1.

In some embodiments, dummy sub-pixels may be disposed adjacent to the third sub-pixel circuit G1 in the direction opposite to the first direction DR1. In addition, the dummy sub-pixels may be disposed adjacent to the third sub-pixel circuit G2 in the first direction DR1.

The first anode electrodes RA1 and RA2, the second anode electrodes BA1 and BA2, and the third anode electrodes GA1 and GA2 may correspond to the anode electrodes AE of FIG. 5.

The third anode electrode GA1 and the first anode electrode RA1 may be arranged in the second direction DR2. The second anode electrode BA1 may be disposed in the first direction DR1 with respect to each of the third anode electrode GA1 and the first anode electrode RA1. In some cases, the second anode electrode BA1 may be disposed adjacent to the third anode electrode GA1 and the first anode electrode RA1 in the first direction DR1.

The third anode electrode GA1 may have a greater surface area than that of the first anode electrode RA1, and the second anode electrode BA1 may have a greater surface area than that of the third anode electrode GA1.

However, embodiments are not limited thereto. For example, the first anode electrode RA1 and the third anode electrode GA1 may have substantially the same area as each other, and the second anode electrode BA1 may have a greater area than each of the first and third anode electrodes RA1 and GA1. As such, the areas of the first to third anode electrodes RA1, BA1, and GA1 may be variously modified according to embodiments.

In addition, each of the first to third anode electrodes (RA2, BA2, GA2) of the second pixel PXL2 may be disposed in a similar configuration as each of the first to third anode electrodes (RA1, BA1, GA1) of the first pixel PXL1. For example, the second anode electrode BA1 of the first pixel PXL1 may be disposed adjacent to the third anode electrode GA2 and the first anode electrode RA2 of the second pixel PXL2 in the first direction DR1. For example, the second anode electrode BA1 of the first pixel PXL1 may be disposed between the first anode electrode RA1 of the first pixel PXL1 and the first anode electrode RA2 of the second pixel PXL2 in the first direction DR1.

The first sub-pixel circuit R1, the second sub-pixel circuit B1, and the third sub-pixel circuit G2 may be disposed to overlap the corresponding anode electrodes RA1, BA1, and GA2 in a plan view, For example, along the third direction DR3.

However, the first sub-pixel circuit R2, the second sub-pixel circuit B2, and the third sub-pixel circuit G1 may not overlap the corresponding anode electrodes RA2, BA2, and GA1 in a plan view.

Accordingly, the wiring electrically connecting the first sub-pixel circuit R2 and the first anode electrode RA2, the wiring electrically connecting the second sub-pixel circuit B2 and the second anode electrode BA2, and the wiring electrically connecting the third sub-pixel circuit G1 and the third anode electrode GA1 may be disposed to extend in the first direction DR1.

As the wiring electrically connecting the first sub-pixel circuit R2 and the first anode electrode RA2, the wiring electrically connecting the second sub-pixel circuit B2 and the second anode electrode BA2, and the wiring electrically connecting the third sub-pixel circuit G1 and the third anode electrode GA1 extend in the same direction (For example, the first direction DR1), the anode electrodes and the sub-pixel circuits may be implemented without twisting or crossing the wirings.

In FIG. 11, the first sub-pixel circuit R1, the second sub-pixel circuit B1, and the third sub-pixel circuit G2 are illustrated as being disposed to overlap the corresponding anode electrodes RA1, BA1, GA2 in a plan view (For example, along the third direction DR3).

However, the present disclosure is not limited thereto. For example, the anode electrodes RA1, BA1, and GA2 may be diversely shifted in the first direction DR1, the second direction DR2, and the third direction DR3. Accordingly, the first sub-pixel circuit R1, the second sub-pixel circuit B1, and the third sub-pixel circuit G2 may not overlap the corresponding anode electrodes RA1, BA1, and GA2 in a plan view (For example, the third direction DR3).

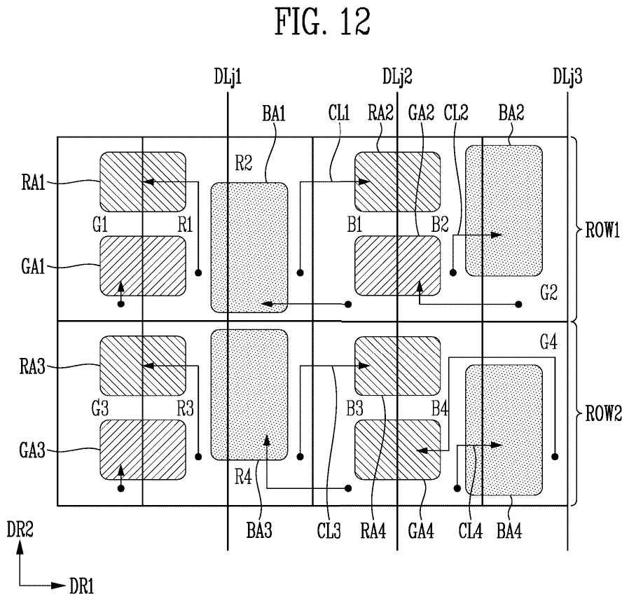

FIG. 12 is a plan view illustrating the connection configuration between the pixel circuit layer PCL and the anode electrode AE according to an embodiment of the present disclosure.

Referring to FIG. 12, the example shown includes first sub-pixel circuits R1, R2, R3, and R4, second sub-pixel circuits B1, B2, B3, and B4, and third sub-pixel circuits G1, G2, G3, and G4, first anode electrodes RA1, RA2, RA3, and RA4, second anode electrodes BA1, BA2, BA3, and BA4, and third anode electrodes GA1, GA2, GA3, and GA4.

The first anode electrode RA1 may be an anode electrode corresponding to the first sub-pixel circuit R1, the first anode electrode RA2 may be an anode electrode corresponding to the first sub-pixel circuit R2, the first anode electrode RA3 may be an anode electrode corresponding to the first sub-pixel circuit R3, and the fourth anode electrode RA4 may be an anode electrode corresponding the first sub-pixel circuit R4. For purpose of illustration, the first to third sub-pixel circuits R1 to R4, B1 to B4, and G1 to G4 are represented by the white boxes. The anode electrodes RA1 to RA4, BA1 to BA4, and GA1 to GA4 are represented by the shaded boxes.

The second anode electrode BA1 may be an anode electrode corresponding to the second sub-pixel circuit B1, the second anode electrode BA2 may be an anode electrode corresponding to the second sub-pixel circuit B2, the second anode electrode BA3 may be an anode electrode corresponding to the second sub-pixel circuit B3, and the second anode electrode BA4 may be an anode electrode corresponding to the second sub-pixel circuit B4.

The third anode electrode GA1 may be an anode electrode corresponding to the third sub-pixel circuit G1, the third anode electrode GA2 may be an anode electrode corresponding to the third sub-pixel circuit G2, the third anode electrode GA3 may be an anode electrode corresponding to the third sub-pixel circuit G3, and the third anode electrodes GA4 may be an anode electrode corresponding to third sub-pixel circuit G4.

The first sub-pixel circuits R1 and R2, the second sub-pixel circuits B1 and B2, and the third sub-pixel circuits G1 and G2 may each correspond to the first sub-pixels R11 and R12, the second sub-pixels B11 and B12, and third sub-pixels G12 and G11 respectively disposed in the i-th row illustrated in FIG. 7.

Each of the first sub-pixel circuits R3 and R4, the second sub-pixel circuits B3 and B4, and the third sub-pixel circuits G3 and G4 may correspond to the first sub-pixels R21 and R22, the second sub-pixels B21 and B22 and the third sub-pixels G22 and G21 respectively disposed in the (i+1)-th row illustrated in FIG. 7.

For example, the first sub-pixel circuit R1 may be a sub-pixel circuit of the first sub-pixel R11, the first sub-pixel circuit R2 may be a sub-pixel circuit of the second sub-pixel R12, the first sub-pixel circuit R3 may be a sub-pixel circuit of the third sub-pixel R21, and the first sub-pixel R4 may be a sub-pixel circuit of the second sub-pixel R22.

The second sub-pixel circuit B1 may be a sub-pixel circuit of the second sub-pixel B11, the second sub-pixel circuit B2 may be a sub-pixel circuit of the second sub-pixel B12, the second sub-pixel circuit B3 may be a sub-pixel circuit of the second sub-pixel B21, and the second sub-pixel circuit B4 may be a sub-pixel circuit of the second sub-pixel B22.

The third sub-pixel circuit G1 and the third sub-pixel circuit G3 may be dummy pixels or sub-pixel circuits of sub-pixels disposed on the left side of the first pixel PXL1 in FIG. 7. The third sub-pixel circuit G2 may be a sub-pixel circuit of the third sub-pixel G12, and the third sub-pixel circuit G4 may be a sub-pixel circuit of the first sub-pixel G22.

Referring to the first row ROW1, the third sub-pixel circuit G1, the first sub-pixel circuit R1, the first sub-pixel circuit R2, the second sub-pixel circuit B1, the second sub-pixel circuit B2, and the third sub-pixel circuit G2 may be sequentially disposed in the first direction DR1.

The first sub-pixel circuit R1 and the second sub-pixel circuit B1 may be included in the first pixel PXL1 of FIG. 7. The third sub-pixel circuit G1 may be included in the dummy pixel or the sub-pixel disposed on the left side of the first pixel PXL1. The first sub-pixel circuit R2, the second sub-pixel circuit B2, and the third sub-pixel circuit G2 may be included in the second pixel PXL2 of FIG. 7.

The first sub-pixel circuits R1 and R2 may share the first data line DLj1. The first sub-pixel circuits R1 and R2 may be symmetrically disposed to each other with respect to the first data line DLj1. For example, the distance between the first sub-pixel circuits R1 to the first data line DLj1 is the same as the distance between the first sub-pixel circuits R2 to the first data line DLj1.

The second sub-pixel circuits B1 and B2 may share the second data line DLj2. The second sub-pixel circuits B1 and B2 may be symmetrically disposed to each other with respect to the second data line DLj2. For example, the distance between the second sub-pixel circuits B1 to the second data line DLj2 is the same as the distance between the second sub-pixel circuits B2 to the second data line DLj2.

Referring to the second row ROW2, the third sub-pixel circuit G3, the first sub-pixel circuit R3, the first sub-pixel circuit R4, the second sub-pixel circuit B3, the second sub-pixel circuit B4, and the third sub-pixel circuit G4 may be sequentially disposed in the first direction DR1.

The first sub-pixel circuit R3 and the second sub-pixel circuit B3 may be included in the third pixel PXL3 of FIG. 7. The third sub-pixel circuit G3 may be included in a dummy pixel or a sub-pixel disposed on the left side of the third pixel PXL3. The first sub-pixel circuit R4, the second sub-pixel B4, and the third sub-pixel G4 may be included in the fourth pixel PXL4 of FIG. 7.

The first sub-pixel circuits R3 and R4 may share the first data line DLj1. The first sub-pixel circuits R3 and R4 may be symmetrically disposed to each other with respect to the first data line DLj1. For example, the distance between the first sub-pixel circuits R3 to the first data line DLj1 is the same as the distance between the first sub-pixel circuits R4 to the first data line DLj1.

The second sub-pixel circuits B3 and B4 may share the second data line DLj2. The second sub-pixel circuits B3 and B4 may be symmetrically disposed to each other with respect to the second data line DLj2. For example, the distance between the second sub-pixel circuits B3 to the second data line DLj2 is the same as the distance between the second sub-pixel circuits B4 to the second data line DLj2.

Referring to FIG. 12, the third sub-pixel circuit G1 of the first row ROW1 may be connected to the third anode electrode GA1, the first sub-pixel circuit R1 may be connected to the first anode electrode RA1, the first sub-pixel circuit R2 may be connected to the first anode electrode RA2, the second sub-pixel circuit B1 may be connected to the second anode electrode BA1, the second sub-pixel circuit B2 may be connected to the second anode electrode BA2, and the third sub-pixel circuit G2 may be connected to the third anode electrode GA2.

A first connection path CL1 connecting the first sub-pixel circuit R2 and the first anode electrode RA2, and a second connection path CL2 connecting the second sub-pixel circuit B2 and the second anode electrode BA2 may extend in the first direction DR1. For example, the first connection path CL1 and the second connection path CL2 may extend in the same direction.

In a plan view, the first anode electrode RA1 may overlap the third sub-pixel circuit G1 and the first sub-pixel circuit R1. In a plan view, the third anode electrode GA1 may overlap the third sub-pixel circuit G1 and the first sub-pixel circuit R1. In one aspect, the first anode electrode RA1 and the third anode electrode GA1 may be spaced apart from each other in the second direction DR2. In a plan view, the second anode electrode BA1 may overlap the first sub-pixel circuits R1 and R2.

In a plan view, the first anode electrode RA2 may overlap the second sub-pixel circuits B1 and B2. In a plan view, the third anode electrode GA2 may overlap the second sub-pixel circuits B1 and B2. In one aspect, the first anode electrode RA2 and the third anode electrode GA2 may be spaced apart from each other in the second direction DR2. In a plan view, the second anode electrode BA2 may overlap the second sub-pixel circuit B2 and the third sub-pixel circuit G2.

Referring to FIG. 12, the third sub-pixel circuit G3 in the second row ROW2 may be connected to the third anode electrode GA3, the first sub-pixel circuit R3 may be connected to the first anode electrode RA3, the first sub-pixel circuit R4 may be connected to the first anode electrode RA4, the second sub-pixel circuit B3 may be connected to the second anode electrode BA3, the second sub-pixel circuit B4 may be connected to the second anode electrode BA4, and the third sub-pixel circuit G4 may be connected to the third anode electrode GA4.

A third connection path CL3 connecting the first sub-pixel circuit R4 and the first anode electrode RA4, and a fourth connection path CL4 connecting the second sub-pixel circuit B4 and the second anode electrode BA4 may extend in the first direction DR1. For example, the third connection path CL3 and the fourth connection path CL4 may extend in the same direction (e.g., the first direction DR1).

Similar to the configuration of the anode electrodes and the sub-pixel circuit in the first row ROW1, the first anode electrode RA3 may overlap the third sub-pixel circuit G3 and the first sub-pixel circuit R3 in the plan view. In a plan view, the third anode electrode GA3 may overlap the third sub-pixel circuit G3 and the first sub-pixel circuit R3. In one aspect, the first anode electrode RA3 and the third anode electrode GA3 may be spaced apart from each other in the second direction DR2. In a plan view, the second anode electrode BA3 may overlap the first sub-pixel circuits R3 and R4.

In a plan view, the first anode electrode RA4 may overlap the second sub-pixel circuits B3 and B4. In a plan view, the third anode electrode GA4 may overlap the second sub-pixel circuits B3 and B4. In one aspect, the first anode electrode RA4 and the third anode electrode GA4 may be spaced apart from each other in the second direction DR2. In a plan view, the second anode electrode BA4 may overlap the second sub-pixel circuit B4 and the third sub-pixel circuit G4.

In a plan view, the first data line DLj1 may overlap the second anode electrodes BA1 and BA3. In a plan view, the second data line DLj2 may overlap the first anode electrodes RA2 and RA4 and the third anode electrodes GA2 and GA4. In a plan view, the third data line DLj3 may not overlap the anode electrodes.

The anode electrodes RA1, RA2, BA1, BA2, GA1, and GA2 may be diversly shifted in the first direction DR1 and the second direction DR2. Accordingly, the overlapping connection in the plane between the sub-pixel circuits and the anode electrodes is not limited to that of FIG. 12, and may be different according to some embodiments. In addition, a path connecting the sub-pixel circuits and the anode electrodes is not limited to that of FIG. 12, and may be different according to some embodiments.

Accordingly, the wiring configuration illustrated in FIG. 12 minimizes the twisting of wirings by ensuring that the connection paths CL1-CL4 extend in the same direction (e.g., along the first direction DR1). By structuring the connections between the sub-pixel circuits and the corresponding anode electrodes in a uniform and parallel manner, the embodiments of the present disclosure prevent overlapping or crossing of conductive traces. As a result, unwanted parasitic capacitance is minimized, and thus ensures stable voltage retention in the sub-pixel circuits. Accordingly, the display panel ensures consistent luminance levels and accurate color representation. Additionally, by using a same data line for the same group of sub-pixels, power consumption can be reduced.

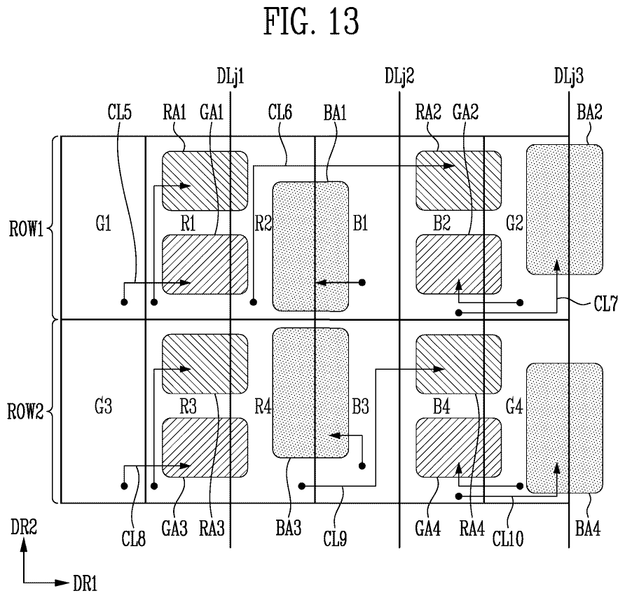

FIG. 13 is a plan view illustrating the connection configuration between the pixel circuit layer PCL and the anode electrode AE according to an embodiment of the present disclosure.

Referring to FIG. 13, the example shown includes the first sub-pixel circuits R1, R2, R3, and R4, the second sub-pixel circuit B1, B2, B3, and B4, and the third sub-pixel circuit G1, G2, G3, and G4, the first anode electrodes RA1, RA2, RA3, and RA4, the second anode electrodes BA1, BA2, BA3, and BA4, and the third anode electrodes GA1, GA2, GA3, and GA4.

The first sub-pixel circuits R1, R2, R3, and R4, the second sub-pixel circuits B1, B2, B3, and B4 and the third sub-pixel circuits G1, G2, G3, and G4, the first anode electrodes RA1, RA2, RA3, and RA4, the second anode electrodes BA1, BA2, BA3, and BA4 and the third anode electrodes GA1, GA2, GA3, and GA4 in FIG. 13 are similar to the first sub-pixel circuits R1, R2 and R3, R4 and the second sub-pixel circuits B1, B2, B3, and B4, the third sub-pixel circuits G1, G2, G3, and G4 and the first anode electrodes RA1, RA2, RA3 and RA4, and the second anode electrodes BA1, BA2, BA3 and BA4, and the third anode electrode GA1, GA2, GA3, GA4 in FIG. 12, respectively, and thus overlapping descriptions thereof may be omitted.

Referring to FIG. 13, the third sub-pixel circuit G1 of the first row ROW1 may be connected to the third anode electrode GA1, the first sub-pixel circuit R1 may be connected to the first anode electrode RA1, the first sub-pixel circuit R2 may be connected to the first anode electrode RA2, the second sub-pixel circuit B1 may be connected to the second anode electrode BA1, the second sub-pixel circuit B2 may be connected to the second anode electrode BA2, and the third sub-pixel circuit G2 may be connected to the third anode electrode GA2.

A fifth connection path CL5 connecting the third sub-pixel circuit G1 and the third anode electrode GA1, a sixth connection path CL6 connecting the first sub-pixel circuit R2 and the first anode electrode RA2, and a seventh connection path CL7 connecting the second sub-pixel circuit B2 and the second anode electrode BA2 may extend in the first direction DR1. For examples, the fifth to seventh connection paths CL5, CL6, and CL7 may extend in the same direction.

In a plan view, the first anode electrode RA1 may overlap the first sub-pixel circuits R1 and R2. In a plan view, the third anode electrode GA1 may overlap the first sub-pixel circuits R1 and R2. In a plan view, the second anode electrode BA1 may overlap the first sub-pixel circuit R2 and the second sub-pixel circuit B1.

In a plan view, the first anode electrode RA2 may overlap the second sub-pixel circuit B2 and the third sub-pixel circuit G2. In a plan view, the third anode electrode GA2 may overlap the second sub-pixel circuit B2 and the third sub-pixel circuit G2. In a plan view, the second anode electrode BA2 may overlap the third sub-pixel circuit G2. In some cases, the second anode electrode BA2 may overlap a portion of the third sub-pixel circuit G1 of a first pixel PXL1 in another pixel group.

Referring to FIG. 13, the third sub-pixel circuit G3 in the second row ROW2 may be connected to the third anode electrode GA3, the first sub-pixel circuit R3 may be connected to the first anode electrode RA3, the first sub-pixel circuit R4 may be connected to the first anode electrode RA4, the second sub-pixel circuit B3 may be connected to the second anode electrode BA3, the second sub-pixel circuit B4 may be connected to the second anode electrode BA4, and the third sub-pixel circuit G4 may be connected to the third anode electrode GA4.

An eighth connection path CL8 connecting the third sub-pixel circuit G3 and the third anode electrode GA3, a ninth connection path CL9 connecting the first sub-pixel circuit R4 and the first anode electrode RA4, and a tenth connection path CL10 connecting the second sub-pixel circuit B4 and the second anode electrode BA4 may extend in the first direction DR1. For example, the eighth to tenth connection paths CL8, CL9, and CL10 may extend in the same direction.

In a plan view, the first anode electrode RA3 may overlap the first sub-pixel circuits R3 and R4. In a plan view, the third anode electrode GA1 may overlap the first sub-pixel circuits R3 and R4. In a plan view, the second anode electrode BA3 may overlap the first sub-pixel circuit R4 and the second sub-pixel circuit B3.

In a plan view, the first anode electrode RA4 may overlap the second sub-pixel circuit B4 and the third sub-pixel circuit G4. In a plan view, the third anode electrode GA4 may overlap the second sub-pixel circuit B4 and the third sub-pixel circuit G4. In a plan view, the second anode electrode BA4 may overlap the third sub-pixel circuit G4. In some cases, the second anode electrode BA4 may overlap a portion of the third sub-pixel circuit G3 of a third pixel PXL3 in another pixel group.

In a plan view, the first data line DLj1 may overlap the first anode electrodes RA1 and RA3 and the third anode electrodes GA1 and GA3. In a plan view, the second data line DLj2 may not overlap the anode electrodes. In a plan view, the third data line DLj3 may overlap the second anode electrodes BA2 and BA4.

The anode electrodes RA1, RA2, BA1, BA2, GA1, and GA2 may be diversly shifted in the first direction DR1 and the second direction DR2. Accordingly, the overlapping connection in a plan view between the sub-pixel circuits and the anode electrodes is not limited to that of FIG. 13, and may be different according to embodiments. In addition, a path connecting the sub-pixel circuits and the anode electrodes is not limited to that of FIG. 12, and may be different according to embodiments.

Accordingly, the wiring configuration illustrated in FIG. 13 minimizes the twisting of wirings by ensuring that the connection paths CL5-CL10 extend in the same direction (e.g., along the first direction DR1). By structuring the connections between the sub-pixel circuits and the corresponding anode electrodes in a uniform and parallel manner, the embodiments of the present disclosure prevent overlapping or crossing of conductive traces. As a result, unwanted parasitic capacitance is minimized, and thus ensures stable voltage retention in the sub-pixel circuits. Accordingly, the display panel ensures consistent luminance levels and accurate color representation. Additionally, by using a same data line for the same group of sub-pixels, power consumption can be reduced.

Referring to FIGS. 12 and 13, the areas of the second anode electrodes BA1, BA2, BA3, and BA4 are illustrated as being greater than the areas of the first anode electrodes RA1, RA2, RA3, and RA4, and the areas of the second anode electrodes BA1, BA2, BA3, and BA4 are illustrated as being greater than the areas of the third anode electrodes GA1, GA2, GA3, and GA4, but the present disclosure is not limited thereto. In some cases, the area of the first anode electrodes RA1, RA2, RA3, and RA4 and the third anode electrodes GA1, GA2, GA3, and GA4 may be substantially the same as each other. However, embodiments are not limited thereto.

In some embodiments, the first to third anode electrodes may have substantially the same area as each other. As such, the areas of each of the first to third anode electrodes may be variously modified according to some embodiments.

In addition, the shape and arrangement of the first to third anode electrodes are not limited to those illustrated in FIGS. 12 and 13. In some embodiments, the shape of each of the first to third anode electrodes may be hexagonal. In some embodiments, the first and second anode electrodes may be disposed in the first direction DR1, and the third anode electrode may be disposed in a direction (or a diagonal direction) inclined by an acute angle with respect to the second direction DR2.

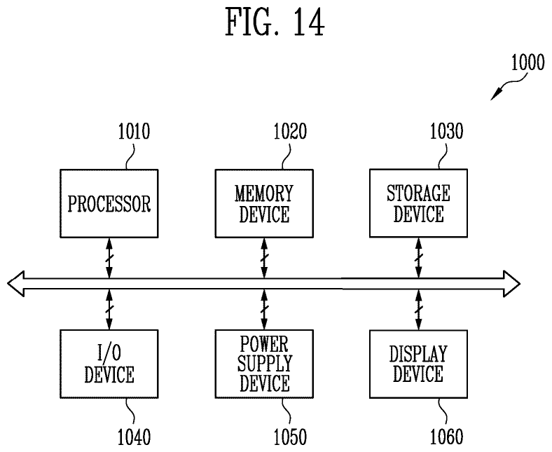

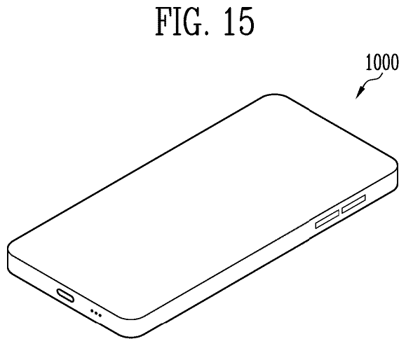

FIG. 14 is a block diagram illustrating an electronic device 1000 according to embodiments of the present invention, and FIG. 15 is a diagram illustrating an example in which the electronic device 1000 is implemented as a smartphone.

Referring to FIGS. 14 and 15, the electronic device 1000 may include a processor 1010, a memory device 1020, a storage device 1030, an input/output device 1040 (or I/O device), a power supply device 1050, and a display device 1060. The display device 1060 may correspond to the display device illustrated in FIG. 1. In addition, the electronic device 1000 may further include various ports that enable communication with other components or devices such as a video card, a sound card, a memory card, a USB device, or the like, or communicate with other systems. In an embodiment, as illustrated in FIG. 15, the electronic device 1000 may be implemented as a smartphone. However, this is mere an example, and the electronic device 1000 is not limited thereto. For example, the electronic device 1000 may be implemented as a mobile phone, a video phone, a smart pad, a smart watch, a tablet PC, a vehicle navigation system, a computer monitor, a notebook, a head mounted display device, or the like.

The processor 1010 may perform certain calculations or tasks. According to an embodiment, the processor 1010 may be a microprocessor, a central processing unit, an application processor, or the like. The processor 1010 may be connected to other components via an address bus, a control bus, a data bus, or the like. According to an embodiment, the processor 1010 may also be connected to an extension bus, such as a Peripheral Component Interconnect (PCI) bus. The processor 1010 may provide the input image data IMG and the control signal CTRL of FIG. 1 to the display device 1060.

The memory device 1020 may store data operational data, system firmware, application software, and other essential information required for the operation of the electronic device 1000. For example, the memory device 1020 may include a non-volatile memory device such as an Erasable Programmable Read-Only Memory (EPROM) device, an Electrically Erasable programmable Read-only Memory (EEPROM) device, a flash memory device, a Phase Change Random Access Memory (PRAM) device, a Resistance Random Access memory (RRAM) device, an Nano Floating Gate Memory (NFGM) device, a Polymer Random Access Memory (PoRAM) device, a Magnetic Random Access Memory (MRAM), a Ferroelectric Random Access Memory (FRAM) device, and/or a volatile memory device such as a Dynamic Random Access Memory (DRAM) device, A Static Random access memory (SRAM) device, or a mobile DRAM device.

Storage device 1030 may be configured to function as long-term storage for the electronic device 1000. For example, the storage device 1030 may include a Solid State Drive (SSD), a Hard Disk Drive (HDD), a CD-ROM, or the like.

The input/output device 1040 may include user input interfaces such as a keyboard, keypad, touchpad, touchscreen, mouse, or the like, and output interfaces such as a speaker, a printer, or the like. According to an embodiment, the display device 1060 may be included in the input/output device 1040.

The power supply device 1050 may supply power necessary for the operation of the electronic device 1000. For example, the power supply device 1050 may be a Power Management Integrated Circuit (PMIC).

The display device 1060 may display an image corresponding to visual information of the electronic device 1000. The display device 1060 may be, but is not limited to, an organic light-emitting display device or a quantum dot light-emitting display device. The display device 1060 may be connected to other components via the buses or other communication links.

The scope of the present invention should not be limited to the contents described in the detailed description of the specification, but should be determined by the claims. All modifications or variations derived from the meaning and scope of the claims and their equivalents are to be construed as included within the scope of the invention.

A display device according to embodiments of the present disclosure, wirings connecting circuits of sub-pixels and anode electrodes are not twisted, and the sub-pixels generating light of the same color share a data line with each other, so that power consumption may be reduced.

However, the effects of the present invention are not limited to the effects described above, and may be variously extended without departing from the spirit and scope of the present invention.

What is claimed is:

1. A display device comprising:
a first pixel including a first sub-pixel, a second sub-pixel, and a third sub-pixel, wherein the first pixel is disposed in a first row; and
a second pixel including a fourth sub-pixel, a fifth sub-pixel, and a sixth sub-pixel, wherein the second pixel is disposed in the first row,
wherein the first sub-pixel and the fourth sub-pixel are adjacent to each other, emit light of a first color, and share a first data line,
wherein the second sub-pixel and the fifth sub-pixel are adjacent to each other, emit light of a second color, and share a second data line,
wherein the sixth sub-pixel and the third sub-pixel are adjacent to each other, emit light of a third color, and share a third data line, and
wherein the fifth sub-pixel is disposed adjacent to the sixth sub-pixel.

2. The display device of claim 1, wherein:
the first sub-pixel and the fourth sub-pixel emit a red color light,
wherein the second sub-pixel and the fifth sub-pixel emit a blue color light,
wherein the third sub-pixel and the sixth sub-pixel emit a green color light, and
wherein sub-pixels emitting the red color light, sub-pixels emitting the blue color light, and sub-pixels emitting the green color light are disposed sequentially in a first direction perpendicular to the first data line.

3. The display device of claim 2, wherein:
an arrangement order between the first sub-pixel and the fourth sub-pixel is same as an arrangement order between the second sub-pixel and the fifth sub-pixel.

4. The display device of claim 3, wherein:
the arrangement order between the first sub-pixel and the fourth sub-pixel is different from an arrangement order between the third sub-pixel and the sixth sub-pixel, and
wherein the first sub-pixel, the fourth sub-pixel, the second sub-pixel, the fifth sub-pixel, the sixth sub-pixel, and the third sub-pixel are sequentially disposed.

5. The display device of claim 1, further comprising:
a third pixel including a seventh sub-pixel, an eighth sub-pixel, and a ninth sub-pixel, wherein the third pixel is disposed in a second row below the first row; and
a fourth pixel including a tenth sub-pixel, an eleventh sub-pixel, and a twelfth sub-pixel, wherein the fourth pixel is disposed in the second row,
wherein the seventh sub-pixel and the tenth sub-pixel are adjacent to each other, emit light of the first color, and share the first data line,
wherein the eighth sub-pixel and the eleventh sub-pixel are adjacent to each other, emit light of the second color, and share the second data line, and
wherein the ninth sub-pixel and the twelfth sub-pixel are adjacent to each other, emit light of the third color, and share the third data line.

6. The display device of claim 5, further comprising:
a data driver applying a data signal to the first data line, the second data line, and the third data line,
wherein the data driver sequentially applies a data signal corresponding to the first sub-pixel, a data signal corresponding to the fourth sub-pixel, a data signal corresponding to the seventh sub-pixel, and a data signal corresponding to the tenth sub-pixel.

7. The display device of claim 6, wherein:
the first sub-pixel is connected to a first odd-numbered gate line,
wherein the fourth sub-pixel is connected to a first even-numbered gate line,
wherein the seventh sub-pixel is connected to a second odd-numbered gate line,
wherein the tenth sub-pixel is connected to a second even-numbered gate line, and
wherein a gate signal applied to the first odd-numbered gate line, the first even-numbered gate line, the second odd-numbered gate line, and the second even-numbered gate line controls timing at which the data signal is applied to the first sub-pixel, the fourth sub-pixel, the seventh sub-pixel, and the tenth sub-pixel, respectively.

8. The display device of claim 5, further comprising:
a data driver applying a data signal to the first data line, the second data line, and the third data line,
wherein the data driver sequentially applies a data signal corresponding to the first sub-pixel, a data signal corresponding to the fourth sub-pixel, a data signal corresponding to the tenth sub-pixel, and a data signal corresponding the seventh sub-pixel.

9. The display device of claim 8, wherein:
the first sub-pixel is connected to a first odd-numbered gate line,
wherein the fourth sub-pixel is connected to a first even-numbered gate line,
wherein the seventh sub-pixel is connected to a second even-numbered gate line,
wherein the tenth sub-pixel is connected to a second odd-numbered gate line, and
wherein a gate signal applied to the first odd-numbered gate line, the first even-numbered gate line, the second odd-numbered gate line, and the second even-numbered gate line controls timing at which the data signal is applied to the first sub-pixel, the fourth sub-pixel, the seventh sub-pixel, and the tenth sub-pixel, respectively.

10. The display device of claim 5, further comprising:
a pixel circuit layer including a first sub-pixel circuit of the first sub-pixel, a second sub-pixel circuit of the second sub-pixel, a third sub-pixel circuit of the third sub-pixel, a fourth sub-pixel circuit of the fourth sub-pixel, a fifth sub-pixel circuit of the fifth sub-pixel, and a sixth sub-pixel circuit of the sixth sub-pixel; and
a light-emitting element layer including a first anode electrode of the first sub-pixel, a second anode electrode of the second sub-pixel, a third anode electrode of the third sub-pixel, a fourth anode electrode of the fourth sub-pixel, a fifth anode electrode of the fifth sub-pixel, and a sixth anode electrode of the sixth sub-pixel,
wherein a wiring connected to the fourth sub-pixel circuit and the fourth anode electrode and a wiring connected to the fifth sub-pixel circuit and the fifth anode electrode extend in a same direction.

11. The display device of claim 10, wherein:
the first sub-pixel circuit, the fourth sub-pixel circuit, the second sub-pixel circuit, the fifth sub-pixel circuit, the sixth sub-pixel circuit, and the third sub-pixel circuit are sequentially disposed in a first direction, and
wherein the first anode electrode, the sixth anode electrode, the second anode electrode, the fourth anode electrode, the third anode electrode, and the fifth anode electrode are sequentially disposed in the first direction,
wherein the wiring connected to the fourth sub-pixel circuit and the fourth anode electrode, and the wiring connected to the fifth sub-pixel circuit and the fifth anode electrode extend in the first direction.

12. The display device of claim 10, wherein:
the sixth sub-pixel circuit, the third sub-pixel circuit, the first sub-pixel circuit, the fourth sub-pixel circuit, the second sub-pixel circuit, and the fifth sub-pixel circuit are sequentially disposed in a first direction, and
wherein the first anode electrode, the third anode electrode, the second anode electrode, the fourth anode electrode, the sixth anode electrode, and the fifth anode electrode are sequentially disposed in the first direction.

13. The display device of claim 12, wherein:
the wiring connected to the fourth sub-pixel circuit and the fourth anode electrode, and the wiring connected to the fifth sub-pixel circuit and the fifth anode electrode extend in a direction opposite to the first direction.

14. The display device of claim 10, wherein:
the first anode electrode overlaps the first sub-pixel circuit and the third sub-pixel circuit in a plan view;
the second anode electrode overlaps the first sub-pixel circuit and the fourth sub-pixel circuit in a plan view;
the third anode electrode overlaps the first sub-pixel circuit and the third sub-pixel circuit in a plan view;
the fourth anode electrode overlaps the second sub-pixel circuit and the fifth sub-pixel circuit in a plan view;
the fifth anode electrode overlaps the fifth sub-pixel circuit and the sixth sub-pixel circuit in a plan view; and
the sixth anode electrode overlaps the second sub-pixel circuit and the fifth sub-pixel circuit in a plan view.

15. The display device of claim 14, wherein:
the pixel circuit layer further includes a seventh sub-pixel circuit of the seventh sub-pixel, an eighth sub-pixel circuit of the eighth sub-pixel, a ninth sub-pixel circuit of the ninth sub-pixel, a tenth sub-pixel circuit of the tenth sub-pixel, an eleventh sub-pixel circuit of the eleventh sub-pixel, and a twelfth sub-pixel circuit of the twelfth sub-pixel,
wherein the light-emitting element layer further includes a seventh anode electrode of the seventh sub-pixel, an eighth anode electrode of the eighth sub-pixel, a ninth anode electrode of the ninth sub-pixel, a tenth anode electrode of the tenth sub-pixel, an eleventh anode electrode of the eleventh sub-pixel, and a twelfth anode electrode of the twelfth sub-pixel,
wherein the seventh anode electrode overlaps the seventh sub-pixel circuit and the ninth sub-pixel circuit in a plan view,
wherein the eighth anode electrode overlaps the seventh sub-pixel circuit and the tenth sub-pixel circuit in a plan view,
wherein the ninth anode electrode overlaps the seventh sub-pixel circuit and the ninth sub-pixel circuit in a plan view,
wherein the tenth anode electrode overlaps the eighth sub-pixel circuit and the eleventh sub-pixel circuit in a plan view,
wherein the eleventh anode electrode overlaps the eleventh sub-pixel circuit and the twelfth sub-pixel circuit in a plan view, and
wherein the twelfth anode electrode overlaps the eighth sub-pixel circuit and the eleventh sub-pixel circuit in a plan view.

16. The display device of claim 15, wherein:
the first data line overlaps the second anode electrode and the eighth anode electrode in a plan view,
wherein the second data line overlaps the fourth anode electrode, the sixth anode electrode, the tenth anode electrode, and the twelfth anode electrode in a plan view, and
wherein the third data line does not overlap an anode electrode.

17. The display device of claim 10, wherein:
the first anode electrode overlaps the first sub-pixel circuit and the fourth sub-pixel circuit in a plan view,
the second anode electrode overlaps the fourth sub-pixel circuit and the second sub-pixel circuit in a plan view,
the third anode electrode overlaps the first sub-pixel circuit and the fourth sub-pixel circuit in a plan view,
the fourth anode electrode overlaps the fifth sub-pixel circuit and the sixth sub-pixel circuit in a plan view,
the fifth anode electrode overlaps the sixth sub-pixel circuit in a plan view, and
the sixth anode electrode overlaps the fifth sub-pixel circuit and the sixth sub-pixel circuit in a plan view.

18. The display device of claim 17, wherein:
the pixel circuit layer further includes a seventh sub-pixel circuit of the seventh sub-pixel, an eighth sub-pixel circuit of the eighth sub-pixel, a ninth sub-pixel circuit of the ninth sub-pixel, a tenth sub-pixel circuit of the tenth sub-pixel, an eleventh sub-pixel circuit of the eleventh sub-pixel, and a twelfth sub-pixel circuit of the twelfth sub-pixel,
wherein the light-emitting element layer further includes a seventh anode electrode of the seventh sub-pixel, an eighth anode electrode of the eighth sub-pixel, a ninth anode electrode of the ninth sub-pixel, a tenth anode electrode of the tenth sub-pixel, an eleventh anode electrode of the eleventh sub-pixel, and a twelfth anode electrode of the twelfth sub-pixel,
wherein the seventh anode electrode overlaps the seventh sub-pixel circuit and the tenth sub-pixel circuit in a plan view,
wherein the eighth anode electrode overlaps the tenth sub-pixel circuit and the eighth sub-pixel circuit in a plan view,
wherein the ninth anode electrode overlaps the seventh sub-pixel circuit and the tenth sub-pixel circuit in a plan view,
wherein the tenth anode electrode overlaps the eleventh sub-pixel circuit and the twelfth sub-pixel circuit in a plan view,
wherein the eleventh anode electrode overlaps the twelfth sub-pixel circuit in a plan view, and
wherein the twelfth anode electrode overlaps the eleventh sub-pixel circuit and the twelfth sub-pixel circuit in a plan view.

19. The display device of claim 18, wherein:
the first data line overlaps the first anode electrode, the third anode electrode, the seventh anode electrode, and the ninth anode electrode in a plan view,
wherein the second data line does not overlap an anode electrode in a plan view, and
wherein the third data line overlaps the fifth anode electrode and the eleventh anode electrode in a plan view.

20. An electronic device comprising:
a processor; and
a display device displaying an image under controlling of the processor,
wherein the display device includes:
a first pixel including a first sub-pixel, a second sub-pixel, and a third sub-pixel; and
a second pixel including a fourth sub-pixel, a fifth sub-pixel, and a sixth sub-pixel, wherein the second pixel is disposed in a same row as the first pixel,
wherein the first sub-pixel and the fourth sub-pixel are adjacent to each other, emit a red light, and share a first data line,
wherein the second sub-pixel and the fifth sub-pixel are adjacent to each other, emit a blue light, and share a second data line, and
wherein the third sub-pixel and the sixth sub-pixel are adjacent to each other, emit a green light, and share a third data line.
